(19) United States
(12) Patent Application Publication
(10) Pub. No.: US 2025/0374617 A1
(43) Pub. Date: Dec. 4, 2025

(54) DIELECTRIC FRAME STRUCTURES TO MITIGATE LAYOUT- DEPENDENT EFFECT IN SEMICONDUCTOR DEVICES

(71) Applicant: Taiwan Semiconductor Manufacturing Company, Ltd., Hsinchu (TW)

(72) Inventor: Tzu-Ging LIN, Kaohsiung City (TW)

(73) Assignee: Taiwan Semiconductor Manufacturing Company, Ltd., Hsinchu (TW)

(21) Appl. No.: 19/295,586

(22) Filed: Aug. 9, 2025

Related U.S. Application Data
(63) Continuation of application No. 18/649,262, filed on Apr. 29, 2024.
(60) Provisional application No. 63/610,339, filed on Dec. 14, 2023.

(51) Int. Cl. H10D 62/10; H01L 21/762; H10D 30/01; H10D 30/43; H10D 30/67; H10D 84/83

(52) U.S. Cl. CPC H10D 62/115; H01L 21/76224; H10D 30/014; H10D 30/43; H10D 30/6735; H10D 30/6757; H10D 84/834

(57) ABSTRACT

The present disclosure describes a semiconductor device having a dielectric frame structure. The semiconductor device includes a channel structure on a substrate and extending along a first direction, a gate structure on the channel structure and extending along a second direction different from the first direction, a dielectric frame structure on the substrate and parallel to the channel structure, and an isolation structure adjacent to the gate structure and extending through the channel structure into the substrate. The dielectric frame structure includes a dielectric material extending through the gate structure to separate the gate structure into two portions. An end portion of the isolation structure is in contact with the dielectric frame structure.

### CROSS-REFERENCE TO RELATED APPLICATION

This application is a continuation application of U.S. Non-Provisional patent application Ser. No. 18/649,262, filed on Apr. 29, 2024, titled “Dielectric Frame Structures to Mitigate Lay-Out-Dependent Effect in Semiconductor Devices,” which claims the benefit of U.S. Provisional Patent Application No. 63/610,339, titled “Approaches to Eliminate the Lay-Out-Dependent Effect in CPODE/CMODE by Implementing Dummy Fins Formed by CPO/CMG Processes,” filed on Dec. 14, 2023, the disclosures of which are incorporated by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates a top-down view of a semiconductor device having a dielectric frame structure, in accordance with some embodiments.

FIG. 2 illustrates an isometric view of a semiconductor device having a dielectric frame structure, in accordance with some embodiments.

FIGS. 3 and 4A-4B illustrate cross-sectional views of a semiconductor device having a dielectric frame structure, in accordance with some embodiments.

FIG. 5 illustrates a schematic diagram of a semiconductor device having a dielectric frame structure, in accordance with some embodiments.

FIG. 6 is a flow diagram of a method for fabricating a semiconductor device having a dielectric frame structure, in accordance with some embodiments.

FIGS. 7-44 illustrate top-down, isometric, and cross-sectional views of a semiconductor device having a dielectric frame structure at various stages of its fabrication, in accordance with some embodiments.

FIG. 45 is a flow diagram of another method for fabricating a semiconductor device having a dielectric frame structure, in accordance with some embodiments.

FIGS. 46-83 illustrate cross-sectional views of a semiconductor device having a dielectric frame structure at various stages of its fabrication using another method, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., +1%, +2%, +3%, +4%, +5%, +10%, +20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, continuous polysilicon on diffusion edge (CPODE) or continuous metal on diffusion edge (CMODE) processes can be used to pattern nanostructure transistors with trench isolation structures. The trench isolation structures can reduce leakage current through source/drain (S/D) epitaxial structures, transistor channels, and substrates. The nanostructure transistors can include finFETs, GAA FETs, nanosheet transistors, nanowire transistors, multi-bridge channel transistors, nano-ribbon transistors, and other similar structured transistors. However, the CPODE and CMODE processes can create tensile and/or compressive forces on surfaces of a substrate, produce deformation of the substrate, and cause a lay-out dependent effect (LDE) of the nanostructure transistors on the substrate. The iso-dense depth loading effect of the LDE can increase leakage current of the nanostructure transistors. The iso-dense critical dimension loading effect of the LDE can cause damage to S/D epitaxial structures. The gate deformation from the LDE can cause a threshold voltage (Vt) shift of the nanostructure transistors.

Various embodiments of the present disclosure provide methods for forming a dielectric frame structure in a semiconductor device (e.g., a nanostructure transistor) and/or other semiconductor devices in an integrated circuit (IC). In some embodiments, a channel structure extending along a first direction can be formed on a substrate. A gate structure can be formed on the channel structure extending along a second direction different from the first direction. An opening can be formed in the gate structure. A dielectric material can be filled in the opening to form a dielectric frame structure parallel to the channel structure and separating the gate structure into two portions. In some embodiments, the dielectric frame structure can include a stiff dielectric material and extend along the first direction. In some embodiments, the stiff dielectric material can have a Young's modulus greater than that of silicon oxide. In some embodiments, the stiff dielectric material can have a Young's modulus greater than about 75 GPa. An isolation structure can be formed adjacent to the gate structure and can extend through the channel structure into the substrate. In some embodiments, an end portion of the isolation structure can be in contact with the dielectric frame structure. In some embodiments, the isolation structure can be formed by CPODE or CMODE processes. In some embodiments, the dielectric frame structure can act as gate isolation structures, such as cut poly-gate (CPO) or cut metal gate (CMG) dielectric structures. In some embodiments, the dielectric frame structure can reduce the deformation of the substrate and minimize the LDE effect of the semiconductor devices on the substrate. Accordingly, the dielectric frame structure can reduce device leakage current, minimize damage to S/D epitaxial structures, and reduce Vt shift of the semiconductor devices on the substrate.

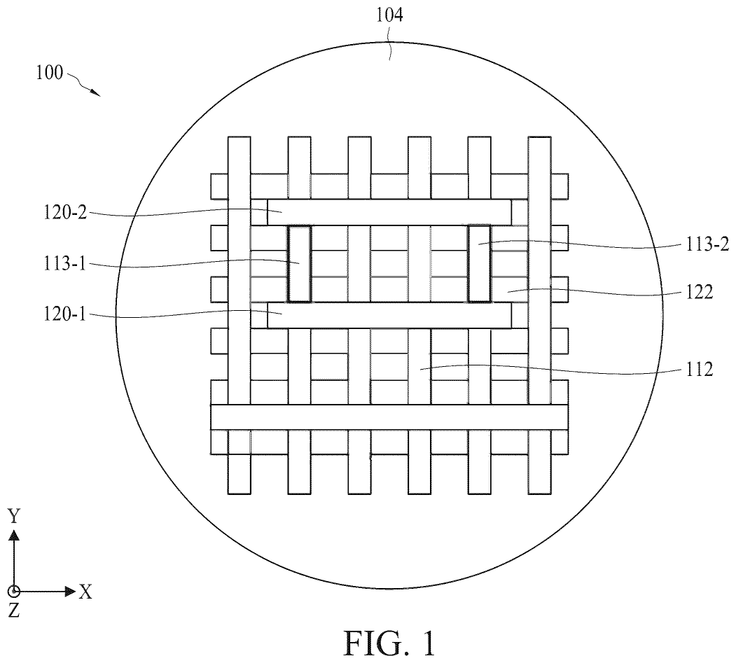

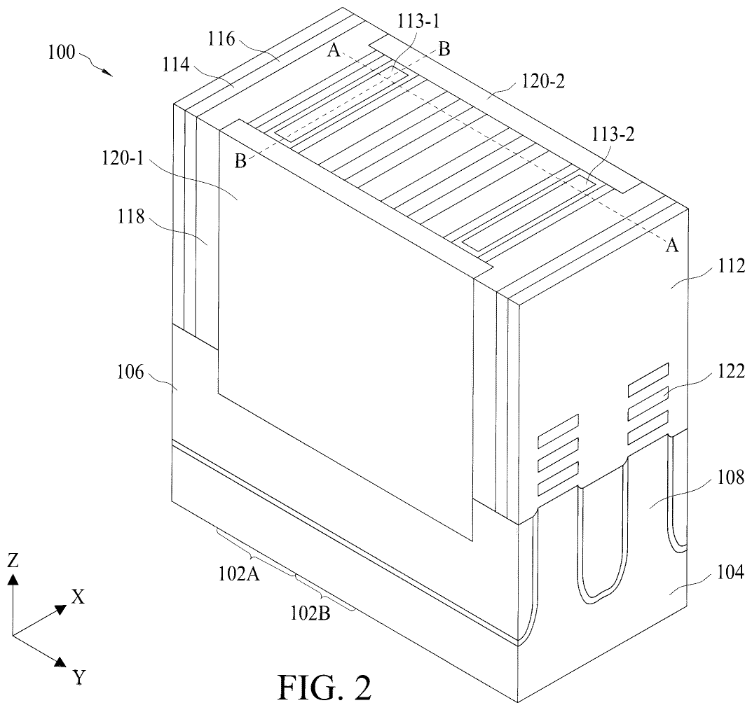

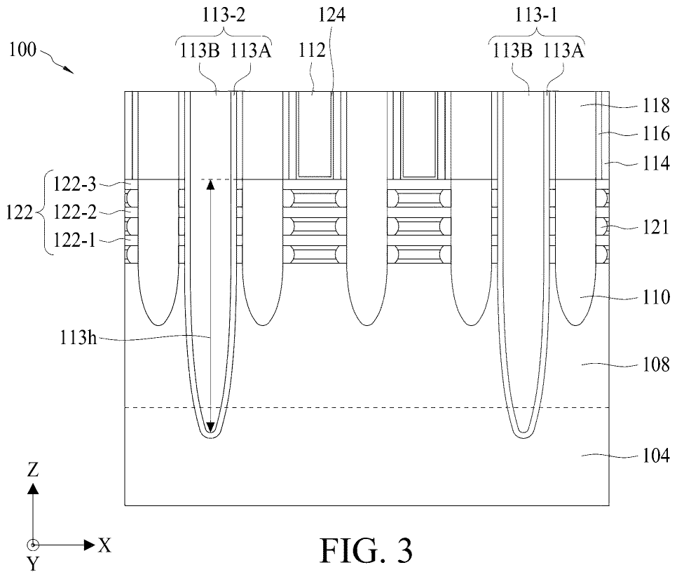

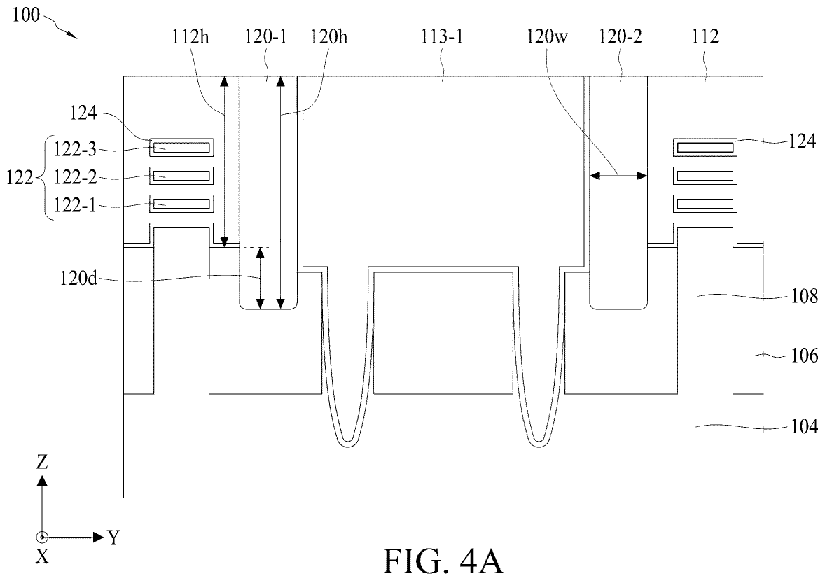

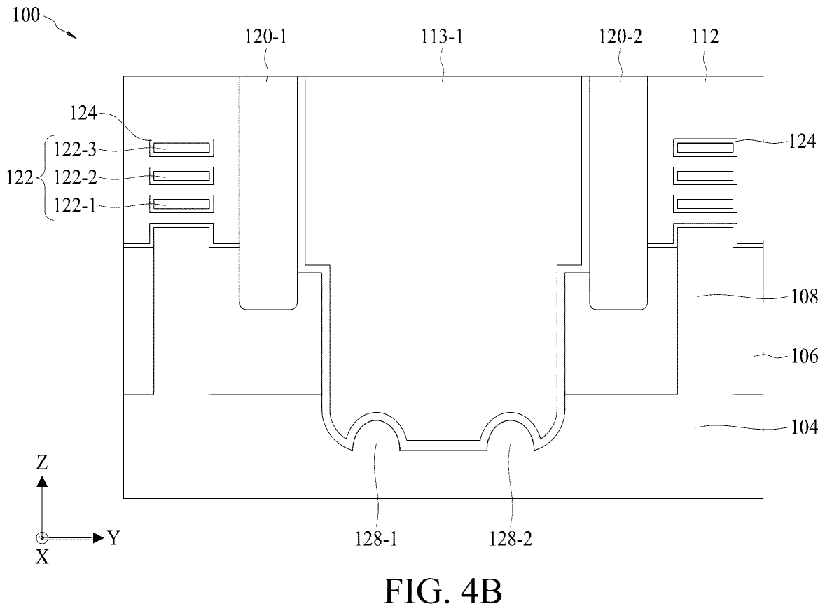

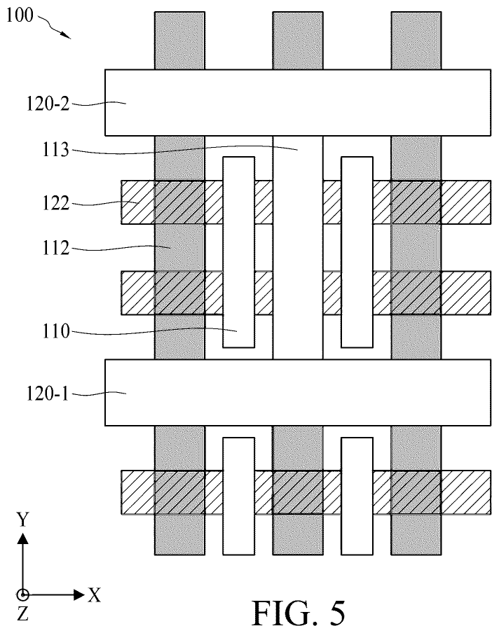

FIG. 1 illustrates a top-down view of a semiconductor device 100 having a dielectric frame structure, in accordance with some embodiments. FIG. 2 illustrates a partial isometric view of semiconductor device 100 having a dielectric frame structure, in accordance with some embodiments. FIGS. 3 and 4A-4B illustrate partial cross-sectional views of semiconductor device 100 having a dielectric frame structure across lines A-A and B-B shown in FIG. 2, respectively, in accordance with some embodiments. FIG. 5 illustrates a schematic diagram of semiconductor device 100 having a dielectric frame structure, in accordance with some embodiments.

In some embodiments, semiconductor device 100 can include transistors 102A-102B, as shown in FIG. 2. In some embodiments, transistors 102A-102B can include nanostructure transistors. The nanostructure transistors can include finFETs, GAA FETs, nanosheet transistors, nanowire transistors, multi-bridge channel transistors, nano-ribbon transistors, and other similar structured transistors. The nanostructure transistors can provide a channel in a fin structure or a stacked nanosheet/nanowire configuration. In some embodiments, transistors 102A-102B can be n-type field-effect transistors (NFETs). In some embodiments, transistors 102A-102B can be p-type field-effect transistors (PFETs). In some embodiments, any of transistors 102A-102B can be an NFET or a PFET. Though FIG. 2 shows two transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102B with the same annotations applies to each other, unless mentioned otherwise. And like reference numerals generally indicate identical, functionally similar, and/or structurally similar elements.

Referring to FIGS. 1-5, semiconductor device 100 having transistors 102A-102B can be formed on a substrate 104 and can be isolated by shallow trench isolation (STI) regions 106. Each of transistors 102A-102B can include fin structures 108, nanostructures 122-1, 122-2, and 122-3 (collectively referred to as “nanostructures 122”), gate dielectric layer 124, gate structures 112, gate spacers 114, inner spacers 121, and S/D structures 110. In some embodiments, semiconductor device 100 can further include trench isolation structures 113-1 and 113-2 (collectively referred to as “trench isolation structures 113”), dielectric frame structures 120-1 and 120-2 (collectively referred to as “dielectric frame structures 120”), an etch stop layer (ESL) 116, and an interlayer dielectric (ILD) layer 118.

Referring to FIGS. 1-5, substrate 104 can include a semiconductor material, such as silicon. In some embodiments, substrate 104 includes a crystalline silicon substrate (e.g., silicon wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102B and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-5, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-5, nanostructures 122 and fin structures 108 can extend along an X-axis. In some embodiments, nanostructures 122 and fin structures 108 can be disposed on substrate 104. Nanostructures 122 can include a stack of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102B. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIGS. 2-5, nanostructures 122 under gate structures 112 can form channel regions of semiconductor device 100 and represent current carrying channel structures of semiconductor device 100. In some embodiments, nanostructures 122 can have a thickness along a Z-axis ranging from about 5 nm to about 8 nm. In some embodiments, nanostructures 122 can have a width along a Y-axis ranging from about 15 nm to about 50 nm. In some embodiments, nanostructures 122 can have a width along an X-axis ranging from about 15 nm to about 25 nm. In some embodiments, a spacing between adjacent nanostructures 122 along a Z-axis can range from about 8 nm to about 12 nm. Though three layers of nanostructures 122 are shown in FIGS. 2-4B, transistors 102A-102B can have any number of nanostructures 122.

Referring to FIGS. 2-4B, gate dielectric layer 124 can be disposed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 2-4B, gate structures 112 can be disposed on gate dielectric layer 124. In some embodiments, gate structures 112 can include one or more work function metal layers and a metal fill. The one or more work function metal layers can include work function metals to tune the Vt of transistors 102A-102B. In some embodiments, gate structures 112 for NFET and PFET devices can have substantially the same work-function metal. In some embodiments, gate structures 112 for NFET and PFET devices can have different work-function metals. In some embodiments, as shown in FIGS. 2-4B, each of nanostructures 122 can be wrapped around by gate structures 112, for which gate structures 112 can be referred to as “gate-all-around (GAA) structures” and transistors 102A-102B can also be referred to as “GAA FETs 102A-102B.” The one or more work function metal layers can wrap around nanostructures 122 and can include work function metals to tune the Vt of transistors 102A-102B. In some embodiments, transistors 102A-102B can include any number of work function metal layers for Vt tuning (e.g., ultra-low Vt, low Vt, and standard Vt). In some embodiments, as shown in FIG. 4A, gate structures 112 can have a height 112h along a Z-axis above top surfaces of STI regions 106. In some embodiments, height 112h can range from about 80 nm to about 120 nm.

In some embodiments, NFETs 102A-102B can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102B can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 2 and 3, gate spacers 114 can be disposed on sidewalls of gate structures 112 and in contact with gate dielectric layer 124, according to some embodiments. Inner spacers 121 can be disposed adjacent to end portions of nanostructures 122 and between S/D structures 110 and gate structures 112. Gate spacers 114 and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114 and inner spacers 121 can include the same insulating material. In some embodiments, gate spacers 114 and inner spacers 121 can include different insulating materials. In some embodiments, gate spacers 114 and inner spacers 121 can include a single layer or a stack of insulating layers. In some embodiments, gate spacers 114 and inner spacers 121 can have a low-k dielectric material with a dielectric constant less than about 3.9 (e.g., about 3.5, about 3.0, or about 2.8).

S/D structures 110 can be disposed on fin structures 108 and on opposing sides of gate structures 112. S/D structures 110 can function as S/D regions of transistors 102A-102B. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. For n-type in-situ doping, n-type doping precursors, such as phosphine, arsine, and other n-type doping precursors, can be used. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. For p-type in-situ doping, p-type doping precursors, such as diborane (B₂H₆), boron trifluoride (BF₃), and other p-type doping precursors, can be used.

In some embodiments, S/D structures 110 can include one or more epitaxial layers, where each epitaxial layer can have different compositions. In some embodiments, each of the one or more epitaxial layers can include Si and differ from each other based on, for example, doping concentration and/or epitaxial growth process conditions. In some embodiments, each of the one or more epitaxial layers can include silicon germanium and differ from each other based on, for example, doping concentration, epitaxial growth process conditions, and/or relative concentration of germanium with respect to silicon.

Referring to FIGS. 1-5, trench isolation structures 113 can be disposed on substrate 104 and on the edge between different diffusion regions (e.g., n and p regions). In some embodiments, trench isolation structures 113 can include a liner 113A and a dielectric fill 113B. In some embodiments, liner 113A can include silicon nitride, silicon carbonitride, or other suitable dielectric materials. Dielectric fill 113B can include silicon oxide, silicon oxynitride, silicon oxycarbonitride, or other suitable dielectric materials. In some embodiments, liner 113A can protect nanostructures 122, fin structures 108, and substrate 104 (e.g., preventing oxidation) during the formation of dielectric fill 113B. In some embodiments, trench isolation structures 113 can extend through gate structures 112, nanostructures 122, STI regions 106, and fin structures 108 into substrate 104. In some embodiments, trench isolation structures 113 can be formed by the CPODE and/or CMODE processes to reduce leakage current flowing through S/D structures 110, nanostructures 122, and substrate 104. In some embodiments, as shown in FIG. 4A, if the CPODE or CMODE process has a high selectivity etching, trench isolation structures 113 can surround a portion of STI regions 106. In some embodiments, as shown in FIG. 4B, if the CPODE or CMODE process has a low selectivity etching, trench isolation structures 113 can extend through STI regions 106 into substrate 104. Bottom surfaces of trench isolation structures 113 can have two recesses corresponding to two bumps 128-1 and 128-2 (collectively referred to as “bumps 128”) on substrate 104.

In some embodiments, as shown in FIGS. 1-5, trench isolation structures 113 can extend over two fin structures 108. In some embodiments, trench isolation structures 113 can extend over one or more than two fin structures 108. In some embodiments, as shown in FIG. 3, trench isolation structures 113 can have a height 113h along a Z-axis from a bottom surface of trench isolation structures 113 to top surfaces of top nanostructures 122-3. Height 113h can range from about 100 nm to about 200 nm. If height 113h is less than about 100 nm, trench isolation structures 113 may not extend through STI regions 106 and may not reduce the leakage current. If height 113h is greater than about 200 nm, the well structures of transistors 102A-102B may be damaged and the device performance may be degraded. Additionally, the leakage current may not be further reduced but manufacturing cost may increase.

Referring to FIGS. 1-5, dielectric frame structures 120 can be disposed on STI regions 106 and between adjacent nanostructures 122. In some embodiments, as shown in FIG. 1, dielectric frame structures 120 and nanostructures 122 can be disposed on substrate 104 in an alternate configuration. Though two dielectric frame structures 120 are shown in FIGS. 1-5, semiconductor device 100 can have any number of dielectric frame structures 120. In some embodiments, dielectric frame structures 120 can include a stiff dielectric material. In some embodiments, the stiff dielectric material can have a Young's modulus greater than that of silicon oxide. In some embodiments, the stiff dielectric material can have a Young's modulus greater than about 75 GPa. In some embodiments, the stiff dielectric material can include hafnium oxide, zirconium oxide, or other suitable high-k dielectric materials. In some embodiments, the stiff dielectric material can include silicon, silicon nitride, silicon carbide, silicon carbonitride, silicon oxycarbonitride, aluminum oxide, or other suitable dielectric materials. In some embodiments, dielectric frame structures 120 can include a single dielectric layer or a stack of dielectric layers having different stiff dielectric materials. In some embodiments, dielectric frame structures 120 can extend vertically through gate structures 112 and can act as gate isolation structures, such as CPO or CMG dielectric structures. Dielectric frame structures 120 can electrically isolate gate structures 112 into multiple portions. In some embodiments, dielectric frame structures 120 can have a higher etch resistivity to remain after various etching processes. In some embodiments, top surfaces of dielectric frame structures 120, trench isolation structures 113, gate structures 112, ILD layer 118, and gate spacers 114 can be substantially coplanar. In some embodiments, end portions of trench isolation structures 113 can be in contact with dielectric frame structures 120.

In some embodiments, as shown in FIG. 4A, dielectric frame structures 120 can have a height 120h along a Z-axis ranging from about 100 nm to about 150 nm. In some embodiments, a ratio of height 120h to height 112h can range from about 1 to about 1.5. In some embodiments, dielectric frame structures 120 can have a width 120w along a Y-axis ranging from about 10 nm to about 20 nm. In some embodiments, dielectric frame structures 120 can extend into STI regions 106 by a depth 120d along a Z-axis ranging from about 50 nm to about 70 nm. Bottom surfaces of dielectric frame structures 120 can be below top surfaces of STI regions 106. If the bottom surfaces of dielectric frame structures 120 is above the top surface of STI regions 106, height 120h is less than about 100 nm, the ratio is less than about 1, or width 120w is less than about 10 nm, dielectric frame structures 120 may not electrically isolate adjacent gate structures 112. If height 120h is greater than about 150 nm, the ratio is greater than about 1.5, depth 120d is greater than about 70 nm, or width 120w is greater than about 20 nm, gate isolation may not be further improved but manufacturing cost may increase.

In some embodiments, dielectric frame structures 120 can reduce the deformation of substrate 104 and minimize the LDE effect of semiconductor device 100 on substrate 104. As shown in FIG. 3, gate structures 112 can be substantially vertical with respect to the X-axis and Y-axis (e.g., top surfaces of nanostructures 122). In some embodiments, gate structures 112 adjacent to trench isolation structures 113 may tilt less than about 2 degrees. In some embodiments, the tilting angles of gate structures 112 at isolated regions and dense regions can vary by less than about 1 degree. As a result, dielectric frame structures 120 can reduce leakage current caused by the iso-dense depth loading effect, minimize damage to S/D epitaxial structures caused by the iso-dense critical dimension loading effect, and reduce Vt shift of semiconductor device 100 caused by gate deformation.

In some embodiments, dielectric frame structures 120 can be formed by the CPO process or the CMG process. Trench isolation structures 113 can be formed by the CPODE process or the CMODE process. In some embodiments, the process to form dielectric frame structures 120 can be identified from the interfaces between gate structures 112 and dielectric frame structures 120. Additionally, the process to form trench isolation structures 113 can be identified from the interfaces between gate structures 112 and trench isolation structures 113. For example, as shown in FIG. 5, if sidewall surfaces of dielectric frame structures 120 is covered with gate structures 112, dielectric frame structures 120 can be formed by the CMG process. If sidewall surfaces of dielectric frame structures 120 is covered with gate dielectric layer 124, dielectric frame structures 120 can be formed by the CPO process. If sidewall surfaces of trench isolation structures 113 is covered with gate structures 112, trench isolation structures 113 can be formed by the CMODE process. If sidewall surfaces of trench isolation structures 113 is covered with gate dielectric layer 124, trench isolation structures 113 can be formed by the CPODE process.

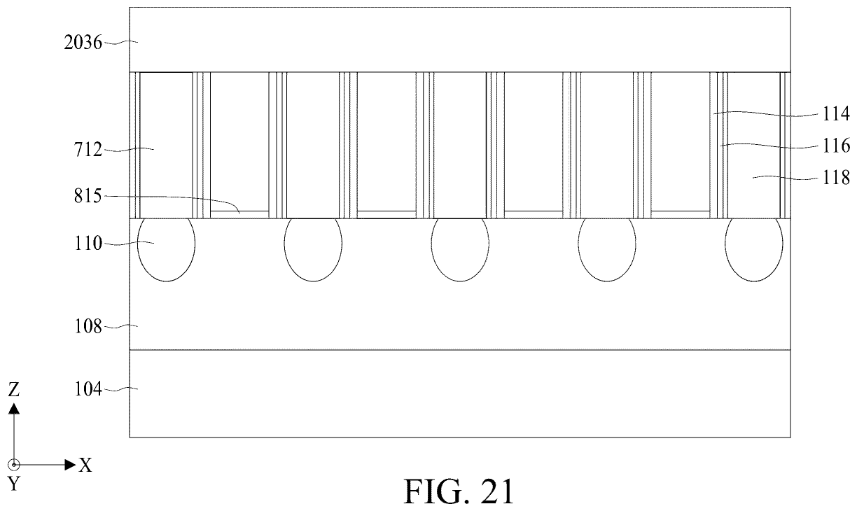

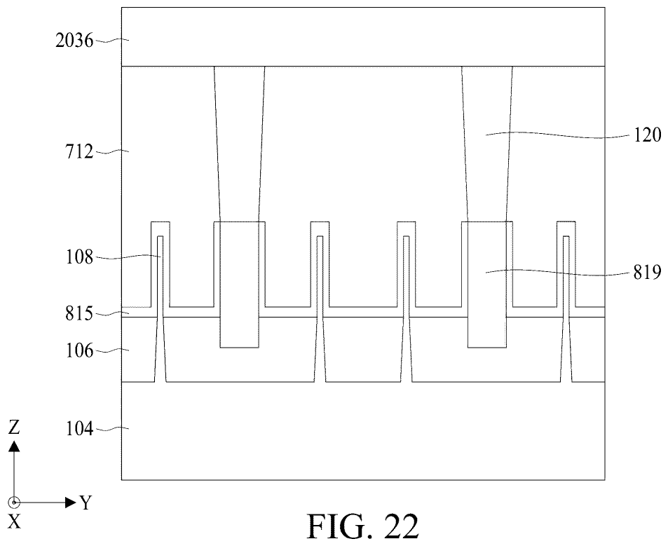

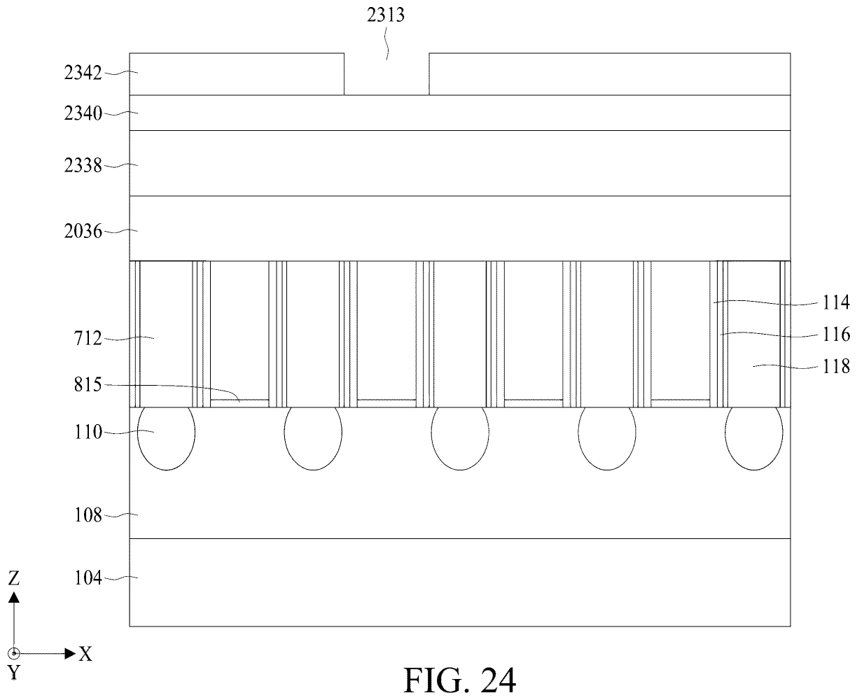

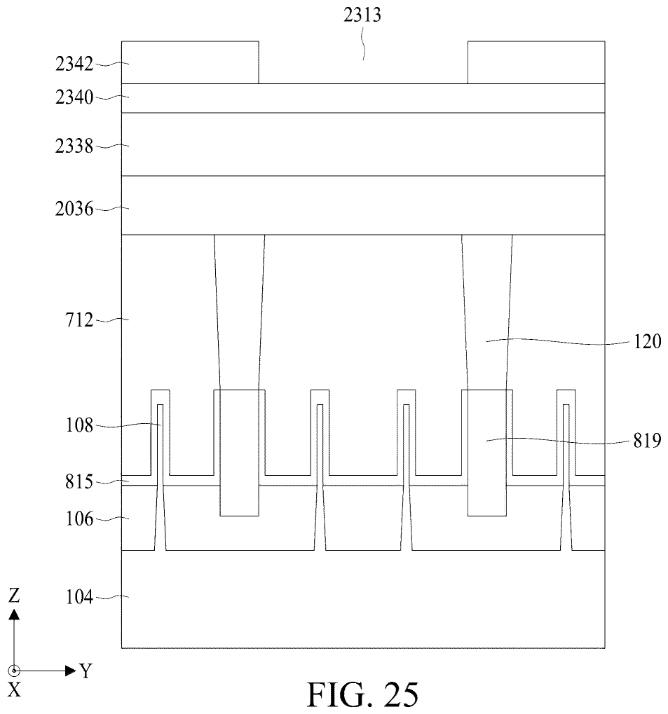

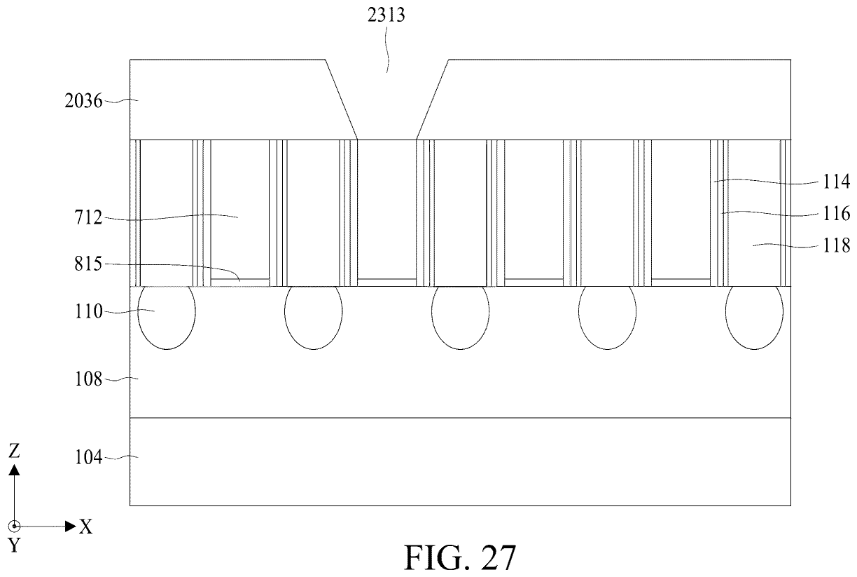

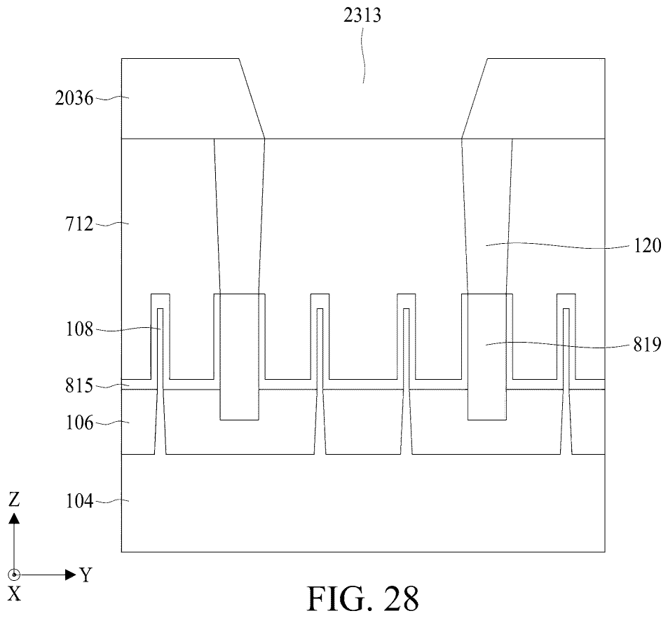

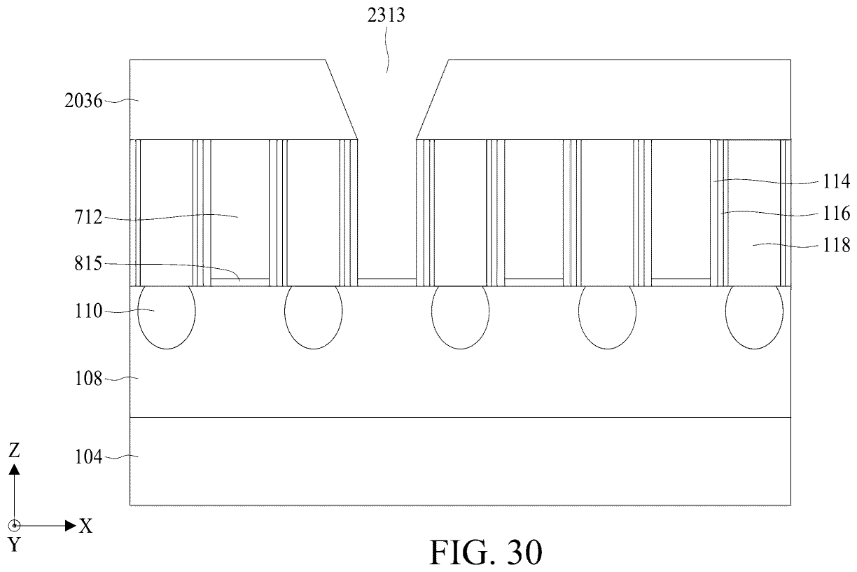

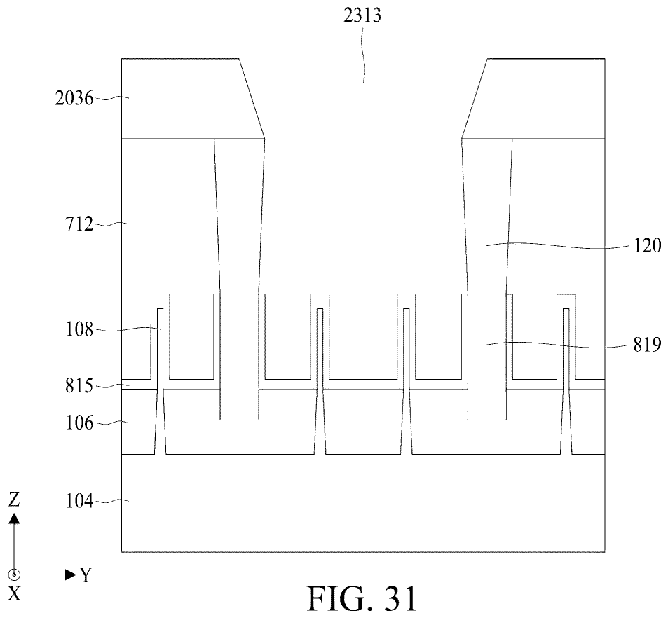

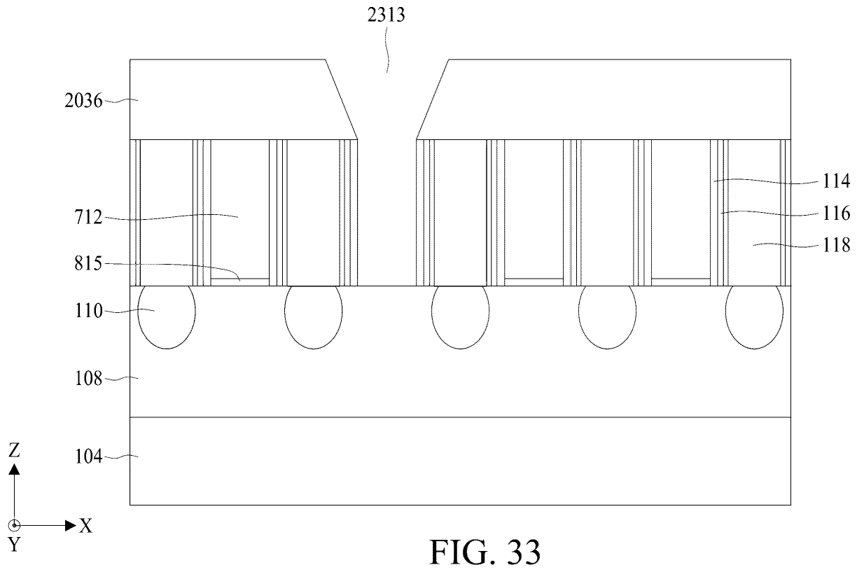

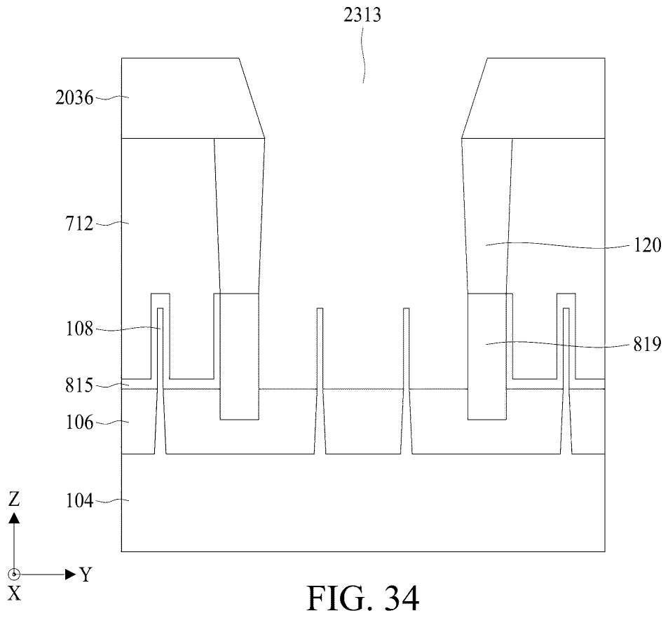

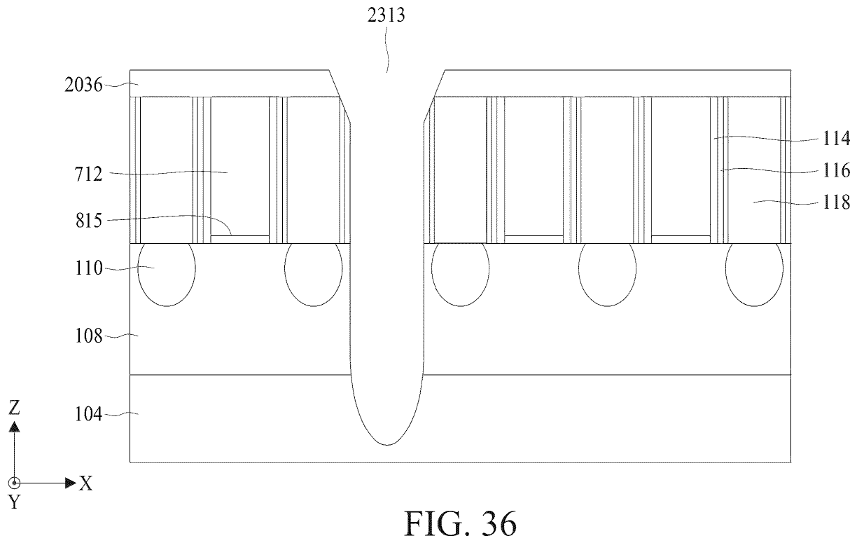

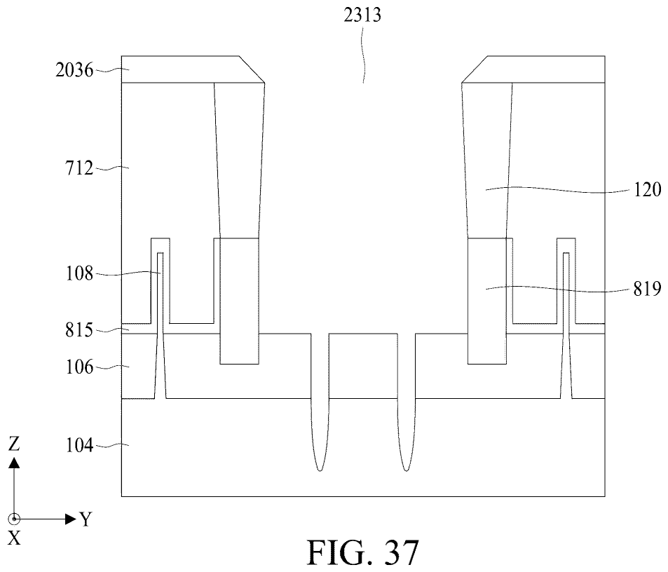

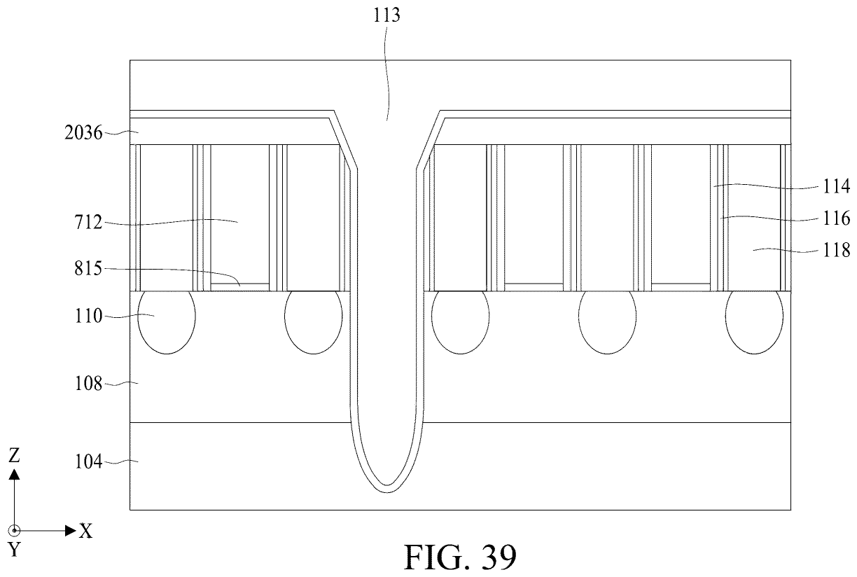

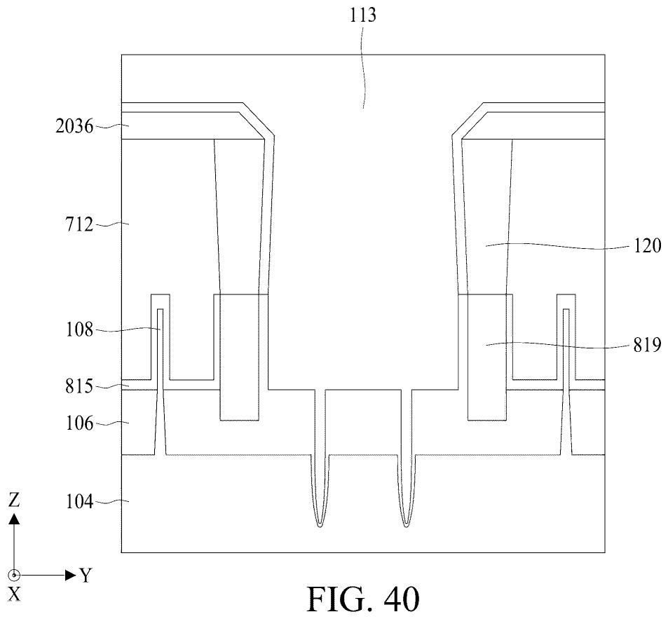

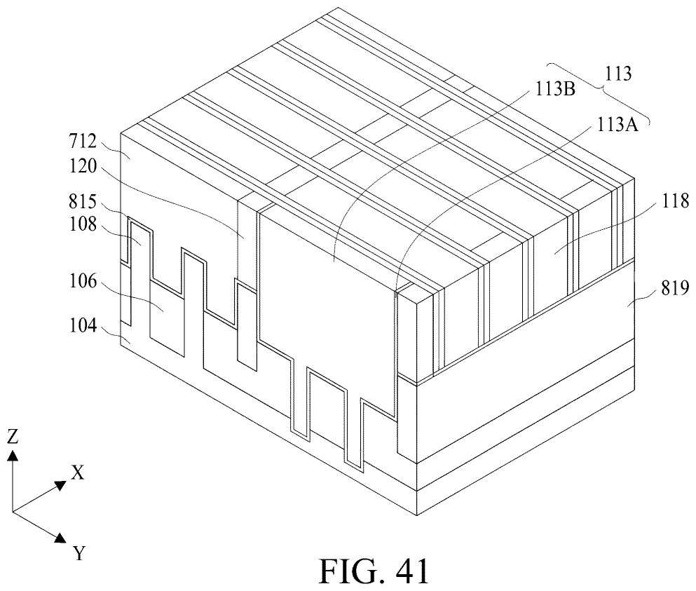

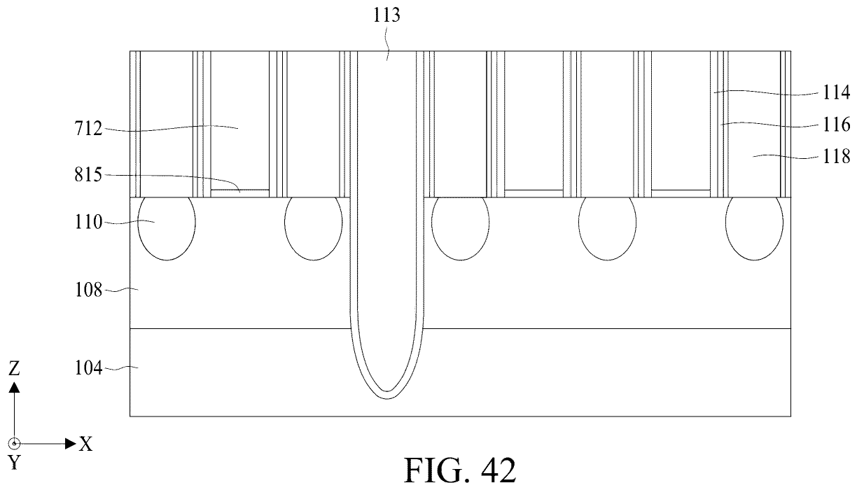

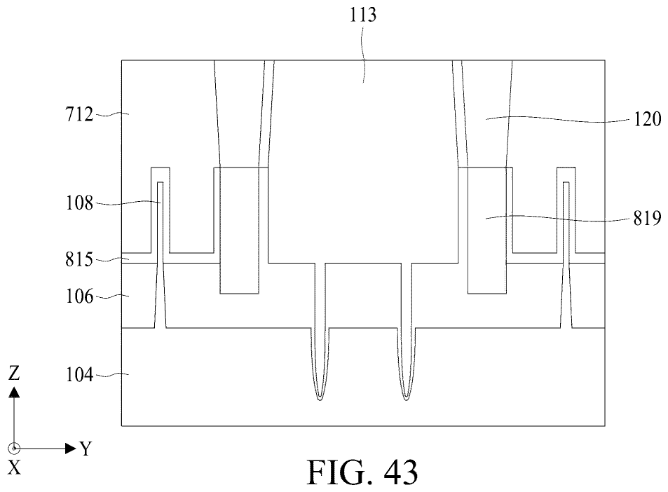

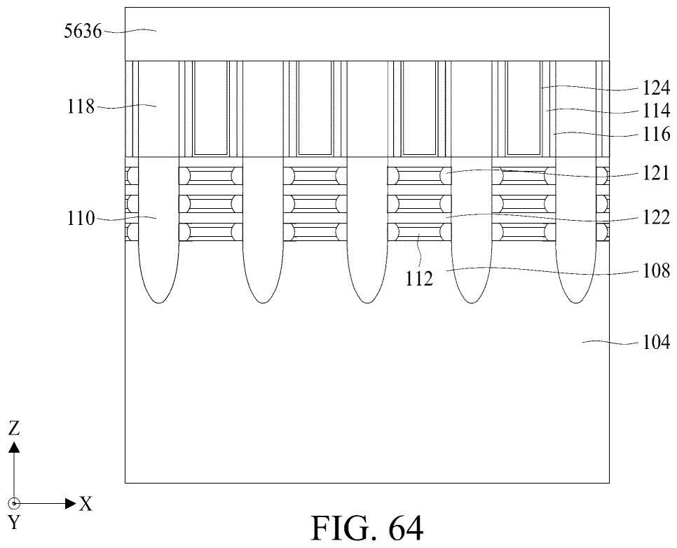

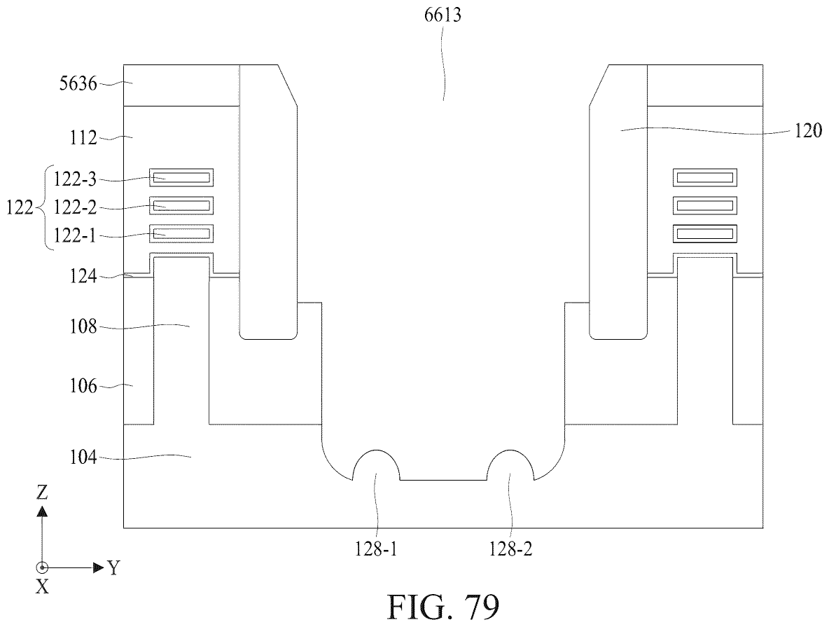

Referring to FIGS. 2-4B, ESL 116 can be disposed on S/D structures 110 and/or sidewalls of gate spacers 114. ESL 116 can be configured to protect S/D structures 110 and/or gate structures 112 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof. In some embodiments, ESL 116 can be optional and can be skipped after the formation of S/D structures 110 by S/D film schemes with a high etch resistance. In some embodiments, ESL 116 may not be shown on S/D structures 110 in FIGS. 21-44 and 46-83.

ILD layer 118 can be disposed on ESL 116 over S/D structures 110. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, semiconductor device 100 can further include S/D contact structures, gate contact structures, metal lines, metal vias, interconnects, and additional ILD layers, which are not described in detail for clarity.

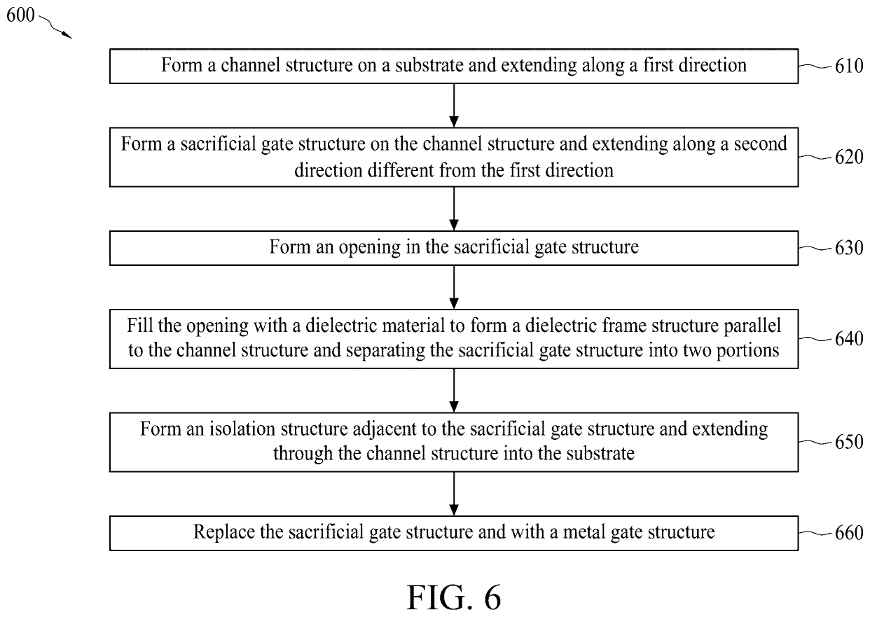

FIG. 6 is a flow diagram of a method 600 for fabricating semiconductor device 100 having a dielectric frame structure, in accordance with some embodiments. Method 600 may not be limited to nanostructure transistor devices and can be applicable to other devices that would benefit from the dielectric frame structure. Additional fabrication operations may be performed between various operations of method 600 and may be omitted merely for clarity and ease of description. Additional processes can be provided before, during, and/or after method 600; one or more of these additional processes are briefly described herein. Moreover, not all operations may be needed to perform the disclosure provided herein. Additionally, some of the operations may be performed simultaneously or in a different order than shown in FIG. 6. In some embodiments, one or more other operations may be performed in addition to or in place of the presently-described operations.

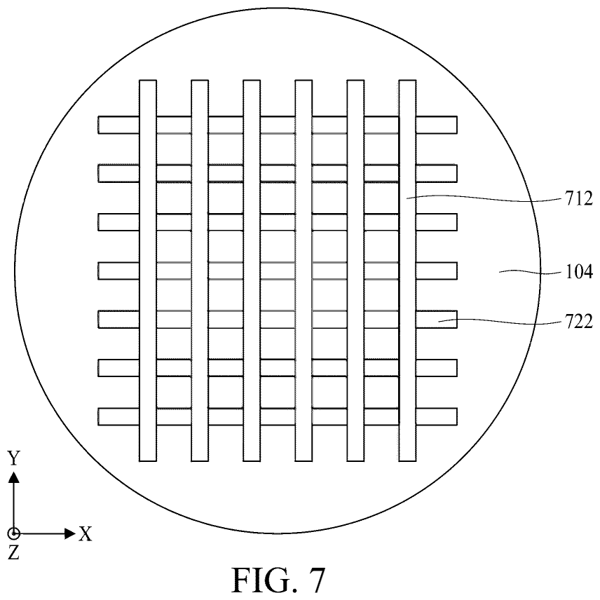

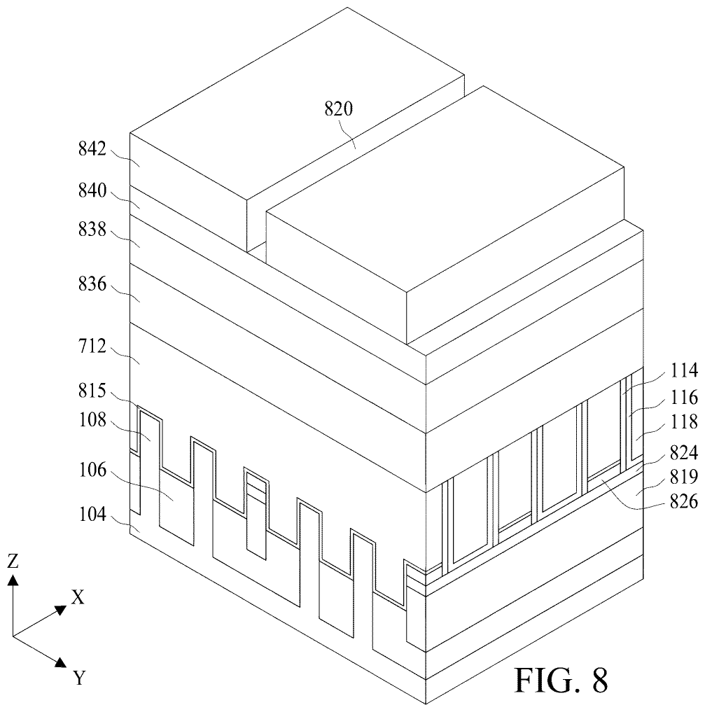

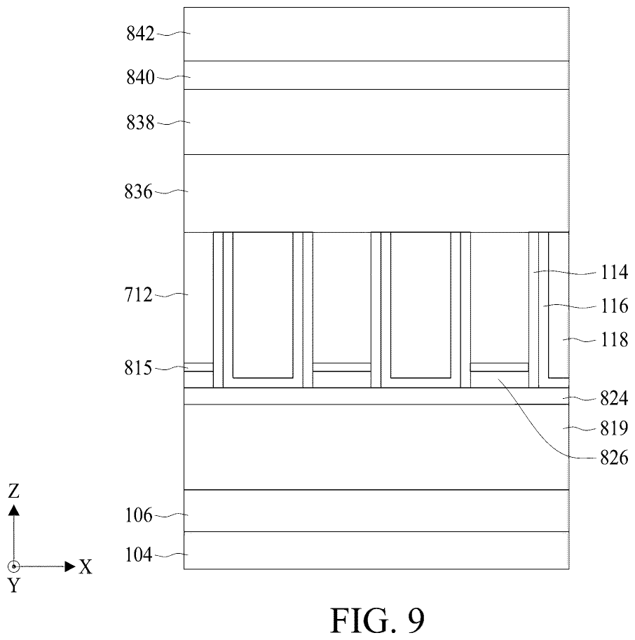

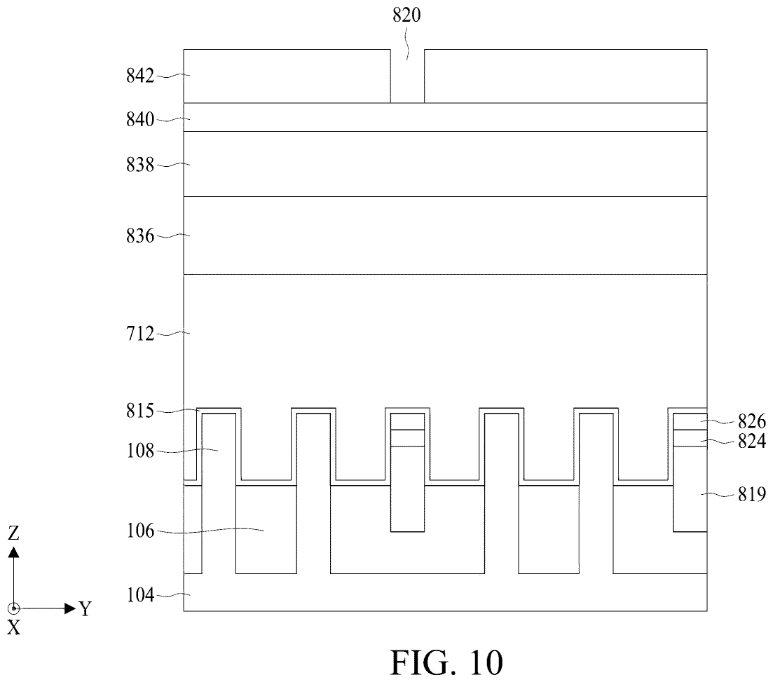

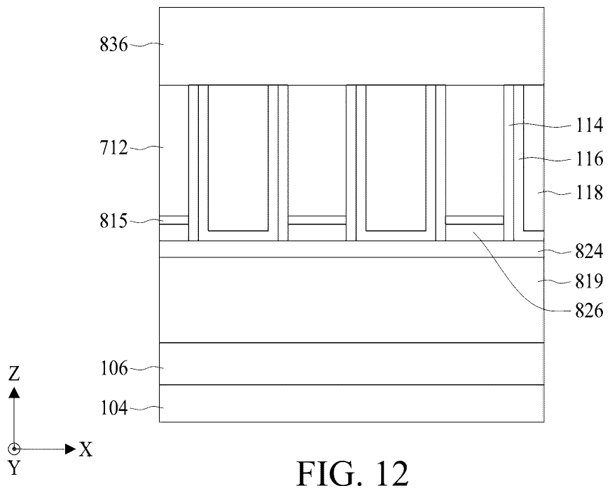

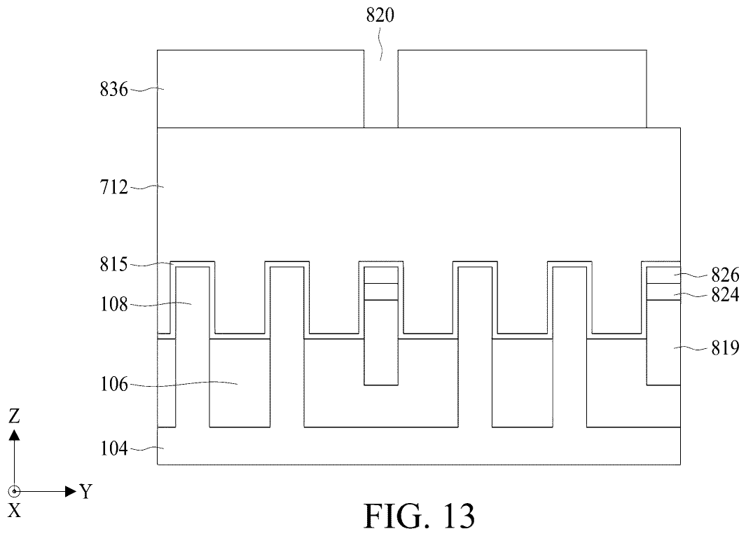

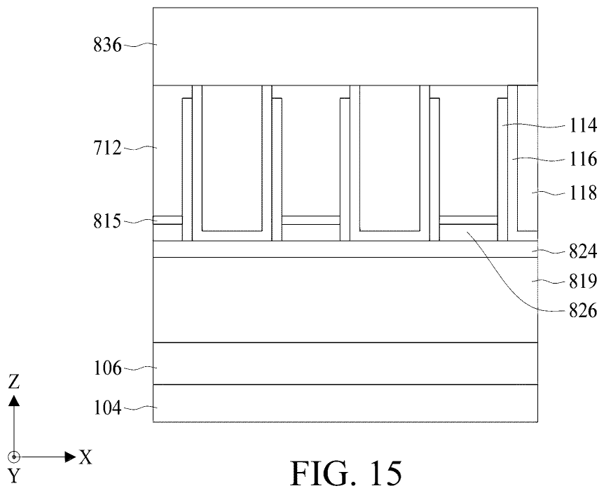

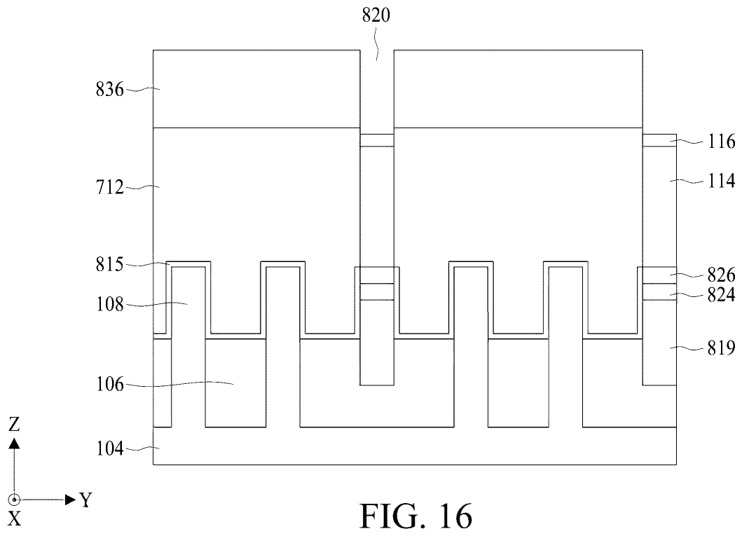

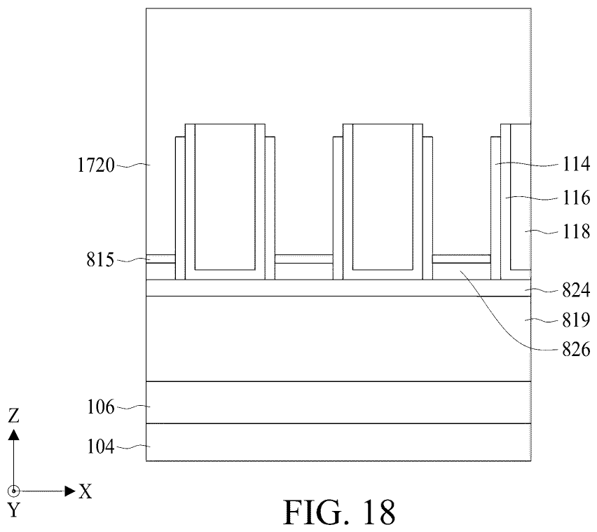

For illustrative purposes, the operations illustrated in FIG. 6 will be described with reference to the example fabrication process for fabricating semiconductor device 100 as illustrated in FIGS. 7-44. FIG. 7 illustrates a top-down view of semiconductor device 100 having a dielectric frame structure, in accordance with some embodiments. FIGS. 8-44 illustrate partial isometric and partial cross-sectional views of semiconductor device 100 having a dielectric frame structure at various stages of its fabrication, in accordance with some embodiments. FIGS. 8, 11, 14, 17, 20, 23, 26, 29, 32, 35, 38, and 41 illustrate partial isometric views of semiconductor device 100 at various stages of its fabrication, in accordance with some embodiments. FIGS. 9, 12, 15, 18, 21, 24, 27, 30, 33, 36, 39, and 42 illustrate partial cross-sectional views of semiconductor device 100 along an X-axis (e.g., line A-A as shown in FIG. 2) at various stages of its fabrication, in accordance with some embodiments. FIGS. 10, 13, 16, 19, 22, 25, 28, 31, 34, 37, 40, 43, and 44 illustrate partial cross-sectional views of semiconductor device 100 along a Y-axis (e.g., line B-B as shown in FIG. 2) at various stages of its fabrication, in accordance with some embodiments. Elements in FIGS. 7-44 with the same annotations as elements in FIGS. 1-5 are described above.

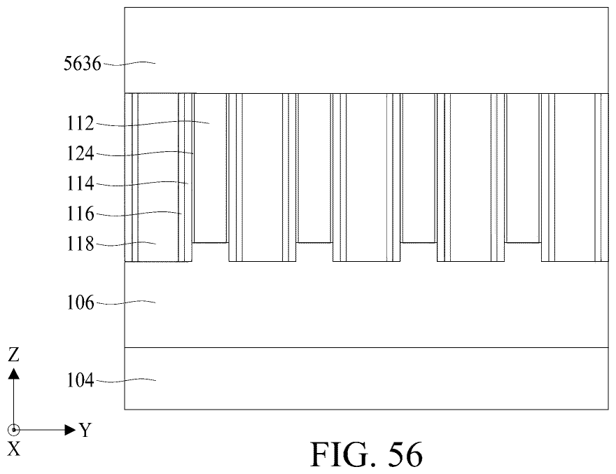

In referring to FIG. 6, method 600 begins with operation 610 and the process of forming a channel structure on a substrate and extending along a first direction. For example, as shown in FIGS. 7-10, fin structures 108 can be formed on substrate 104 along an X-axis. Fin structures 108 can act as the channel structures and covered by a protection layer 815, as shown in FIGS. 8-10. In some embodiments, protection layer 815 can be conformally deposited on STI regions 106 and fin structures 108 to protect fin structures 108 in subsequent etch processes. In some embodiments, protection layer 815 can include silicon oxide or other suitable dielectric materials. In some embodiments, the channel structure can include a stack of nanostructures 122, as shown in FIGS. 56-83 described below.

In some embodiments, fin structures 108 can include semiconductor materials similar to or different from substrate 104. Embodiments of fin structures 108 disclosed herein may be patterned by any suitable method. For example, the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures.

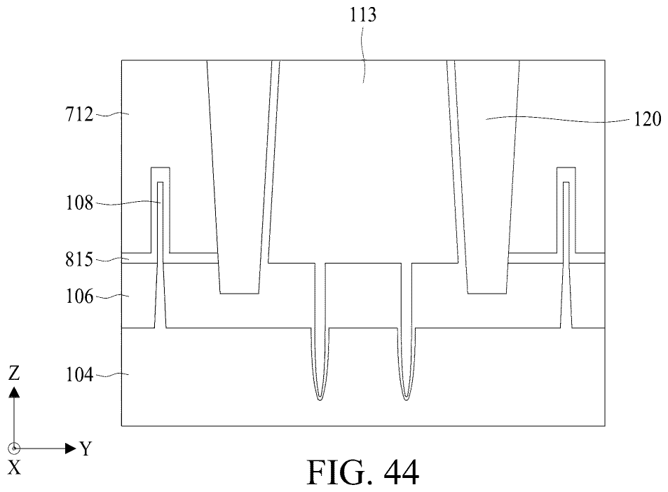

In some embodiments, as shown in FIGS. 8-10, dielectric fin structures 819 can be formed on STI regions 106 and between adjacent fin structures 108. Capping layers 824 and 826 can be formed on dielectric fin structures 819. In some embodiments, dielectric fin structures 819 can include a stiff dielectric material having a Young's modulus greater than that of silicon oxide. In some embodiments, the stiff dielectric material can have a Young's modulus greater than about 75 GPa. In some embodiments, the stiff dielectric material can include hafnium oxide, zirconium oxide, or other suitable high-k dielectric materials. In some embodiments, the stiff dielectric material can include silicon nitride, silicon carbide, silicon carbonitride, silicon oxycarbonitride, silicon, aluminum oxide, or other suitable dielectric materials. In some embodiments, capping layers 824 and 826 can have a higher etching resistivity to protect dielectric fin structures 819 during subsequent etch processes. In some embodiments, capping layer 824 can include silicon oxycarbonitride or other suitable dielectric materials. In some embodiments, capping layer 826 can include silicon nitride or other suitable dielectric materials. In some embodiments, one layer of capping layer 824 or capping layer 826 can be formed on dielectric fin structures 819 to protect dielectric fin structures 819. In some embodiments, capping layers 824 and 826 can be optional. The subsequent etch processes can be highly selective such that capping layers 824 and 826 are not needed to protect dielectric fin structures 819. In some embodiments, dielectric fin structures 819 and capping layers 824 and 826 are optional, as shown in FIG. 44.

Referring to FIG. 6, in operation 620, a sacrificial gate structure can be formed on the channel structure and extending along a second direction different from the first direction. For example, as shown in FIGS. 7-10, sacrificial gate structures 712 can be formed on fin structures 108 extending along a Y-axis. In some embodiments, sacrificial gate structures 712 can include polysilicon or other suitable materials. In some embodiments, sacrificial gate structures 712 can be deposited on protection layer 815 over fin structures 108, dielectric fin structures 819, and STI regions 106. In some embodiments, sacrificial gate structures 712 can be patterned to extend along a Y-axis over fin structures 108. In some embodiments, as shown in FIGS. 8-10, after the formation of sacrificial gate structures 712, gate spacers 114 can be formed on sidewalls of sacrificial gate structures 712. ESL 116 and ILD layer 118 can be formed between adjacent sacrificial gate structures 712. In some embodiments, a chemical mechanical planarization (CMP) process can planarize top surfaces of sacrificial gate structures 712, gate spacers 114, ESL 116, and ILD layer 118. In some embodiments, a hard mask layer 836 can be deposited on the planarized top surfaces of sacrificial gate structures 712, gate spacers 114, ESL 116, and ILD layer 118.

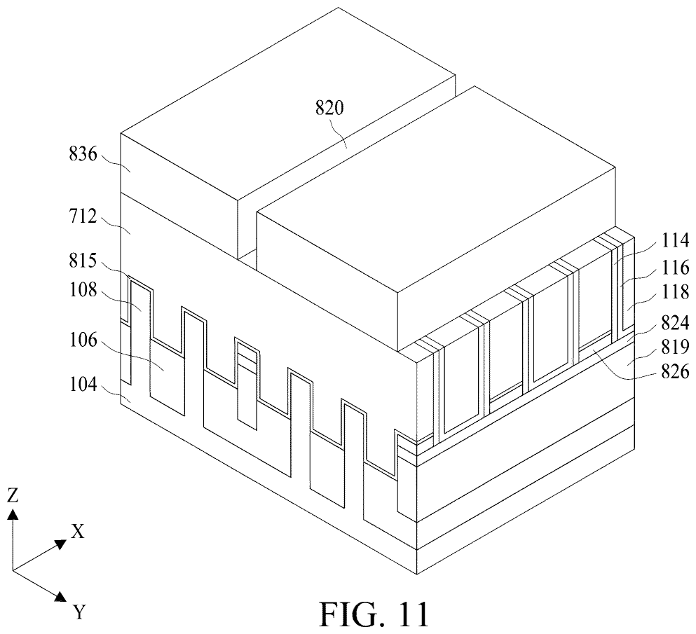

Referring to FIG. 6, in operation 630, an opening is formed in the sacrificial gate structure. For example, as shown in FIGS. 8-16, openings 820 can be formed in sacrificial gate structures 712. In some embodiments, a stack of bottom layer 838, middle layer 840, and photoresist 842 can be deposited on hard mask layer 836. In some embodiments, openings 820 can be patterned in photoresist 842 above sacrificial gate structures 712, as shown in FIGS. 8 and 10. After the patterning process, openings 820 can be formed in hard mask layer 836 by an etching process, as shown in FIGS. 11-13.

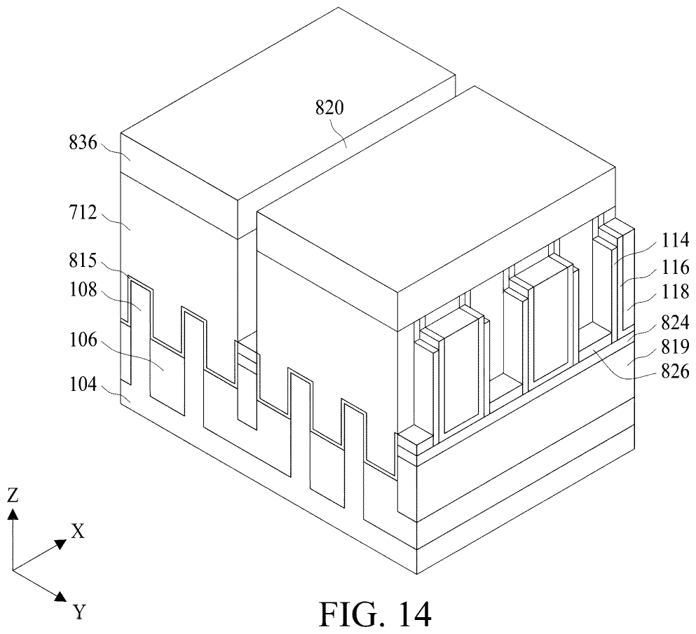

In some embodiments, a dry etching process can remove sacrificial gate structures 712 and extend openings 820 through sacrificial gate structures 712, as shown in FIGS. 14-16. In some embodiments, openings 820 can expose capping layer 826 on dielectric fin structures 819, as shown in FIGS. 14-16. In some embodiments, without dielectric fin structures 819 and capping layers 824 and 826, openings 820 can extend through sacrificial gate structures 712 into STI regions 106, as shown in dielectric frames structures 120 in FIGS. 2, 4A-4B, and 44.

In some embodiments, the etching of sacrificial gate structures 712 can be directional and self-aligned. The etchants can include hydrogen bromide-based plasma with an addition of oxygen or carbon dioxide. In some embodiments, the hydrogen bromide-based plasma can be a high density plasma generated by an inductively coupled plasma or resonant antenna plasma source with a radio-frequency (RF) power generator. In some embodiments, the plasma etching process can use a bias power to increase the directionality of the etching process. In some embodiments, the etching process chamber can be operated at a temperature from about 10° C. to about 200° C. under a pressure ranging from about 1 mTorr to about 200 mTorr.

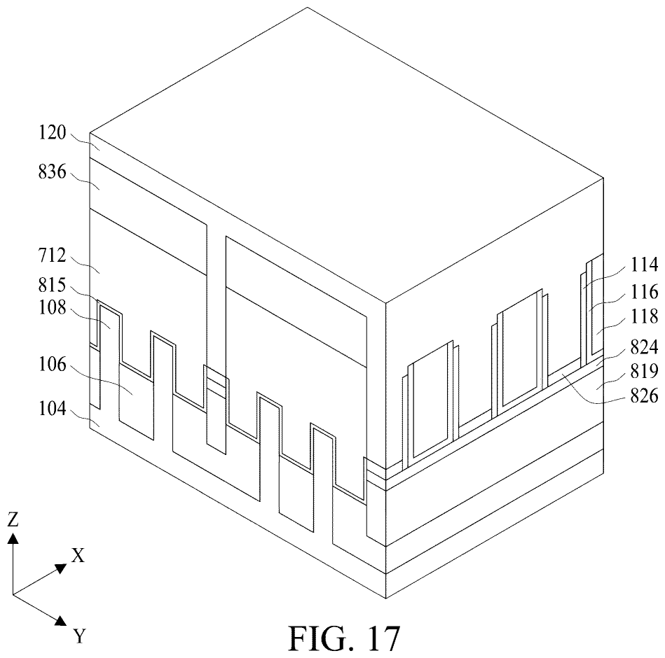

Referring to FIG. 6, in operation 640, a dielectric material is filled in the opening to form a dielectric frame structure parallel to the channel structure and separating the sacrificial gate structure into two portions. For example, as shown in FIGS. 17-19, a stiff dielectric material can be blanket deposited on hard mask layer 836 to fill openings 820 and form dielectric frame structures 120. In some embodiments, dielectric frame structures 120 can extend along an X-axis parallel to nanostructures 122. In some embodiments, dielectric frame structures 120 and dielectric fin structures 819 can extend vertically through gate structures 112. Dielectric frame structures 120 and dielectric fin structures 819 can electrically isolate gate structures 112 into two portions. In some embodiments, as shown in FIGS. 2, 4A-4B, and 44, dielectric frame structures 120 can extend vertically through gate structures 112 into STI regions 106 and can act as gate isolation structures, such as CPO or CMG dielectric structures.

In some embodiments, the stiff dielectric material can have a Young's modulus greater than that of silicon oxide. In some embodiments, the stiff dielectric material can have a Young's modulus greater than about 75 GPa. In some embodiments, the stiff dielectric material can include hafnium oxide, zirconium oxide, or other suitable high-k dielectric materials. In some embodiments, the stiff dielectric material can include silicon nitride, silicon carbide, silicon carbonitride, silicon oxycarbonitride, silicon, aluminum oxide, or other suitable lower k dielectric materials. In some embodiments, dielectric frame structures 120 can have a higher etch resistivity and can remain after the etching during the CPODE and CMODE processes. The formation of dielectric frame structures 120 can be followed by a CMP process to planarize top surfaces of dielectric frame structures 120 and sacrificial gate structures 712.

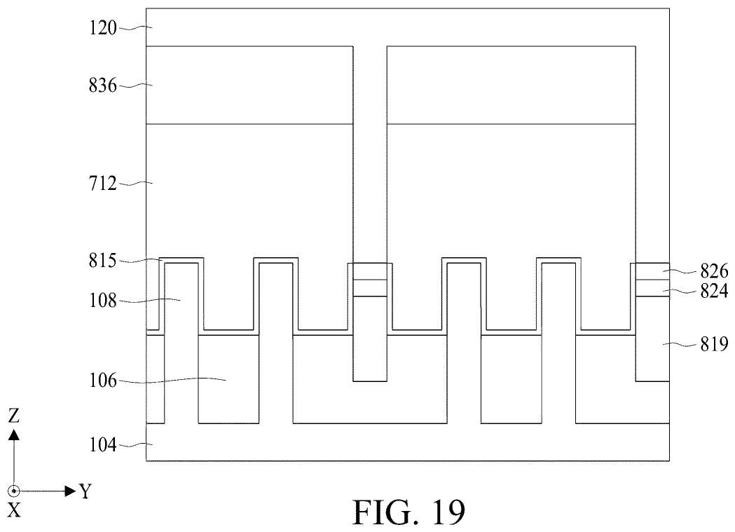

In some embodiments, as shown in FIGS. 17 and 19, dielectric frame structures 120 and fin structures 108 can be disposed on substrate 104 in an alternate configuration. In some embodiments, bottom surfaces of dielectric frame structures 120 can be above the top surfaces of STI regions 106, as shown in FIGS. 17-19. In some embodiments, the bottom surfaces of dielectric frame structures 120 can be below the top surfaces of STI regions 106, as shown in FIGS. 2, 4A-4B, and 44. In some embodiments, dielectric frame structures 120 can reduce the deformation of substrate 104 caused by the CPODE or CMODE processes and minimize the LDE effect of semiconductor device 100 on substrate 104. As a result, dielectric frame structures 120 can reduce leakage current caused by the iso-dense depth loading effect, minimize damage to S/D epitaxial structures caused by the iso-dense critical dimension loading effect, and reduce Vt shift of semiconductor device 100 caused by gate deformation.

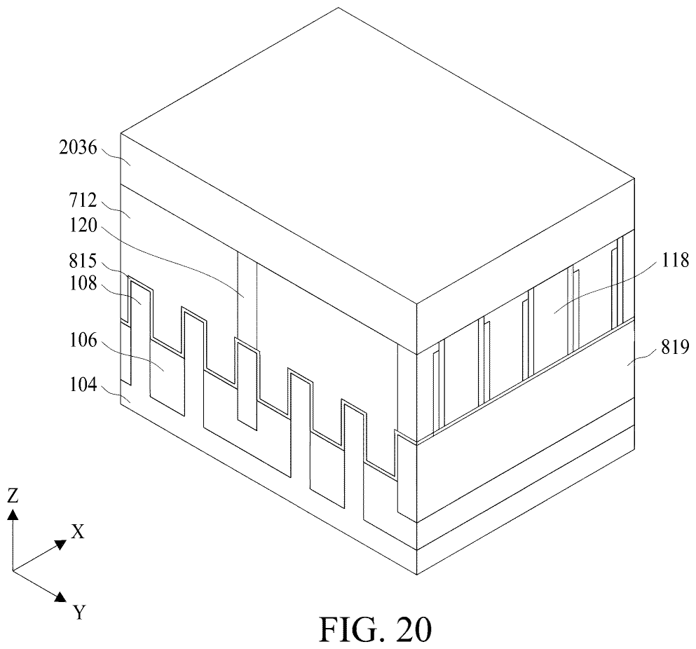

Referring to FIG. 6, in operation 650, an isolation structure is formed adjacent to the sacrificial gate structure and extending through the channel structure into the substrate. For example, as shown in FIGS. 20-43, trench isolation structures 113 can be formed adjacent to sacrificial gate structures 712 and extending through fin structures 108 into substrate 104. In some embodiments, end portions of trench isolation structures 113 can be in contact with dielectric frame structures 120. In some embodiments, the formation of trench isolation structures 113 can include forming an opening 2313 through sacrificial gate structures 712 and fin structures 108 and depositing a dielectric material in opening 2313. In some embodiments, as shown in FIGS. 20-43, protection layer 815 can be formed on fin structures 108 and dielectric fin structures 819 without any capping layers to protect fin structures 108 and dielectric fin structures 819 during subsequent etch processes. The subsequent etch processes can be highly selective such that capping layers are not needed to protect dielectric fin structures 819.

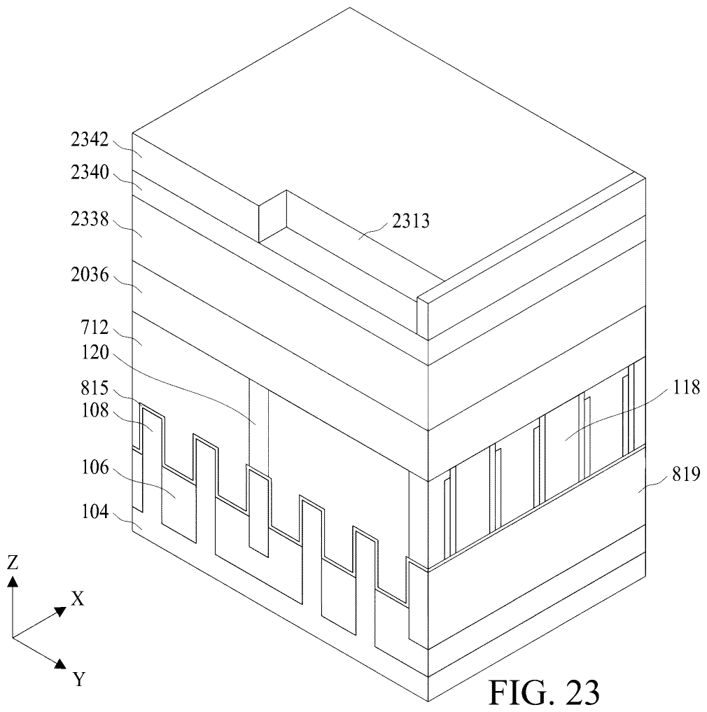

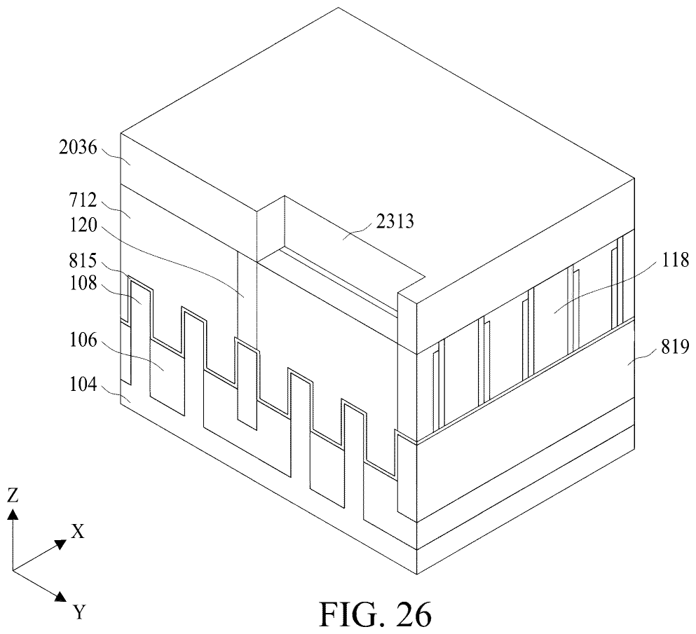

In some embodiments, as shown in FIGS. 20-22, a hard mask layer 2036 can be blanket deposited on planarized top surfaces of dielectric frame structures 120 and sacrificial gate structures 712. In some embodiments, a stack of bottom layer 2338, middle layer 2340, and photoresist 2342 can be deposited on hard mask layer 2036. In some embodiments, opening 2313 can be patterned in photoresist 2342 above sacrificial gate structures 712, as shown in FIGS. 23-25. After the patterning process, opening 2313 can be formed in hard mask layer 2036 by a first etching process, as shown in FIGS. 26-28.

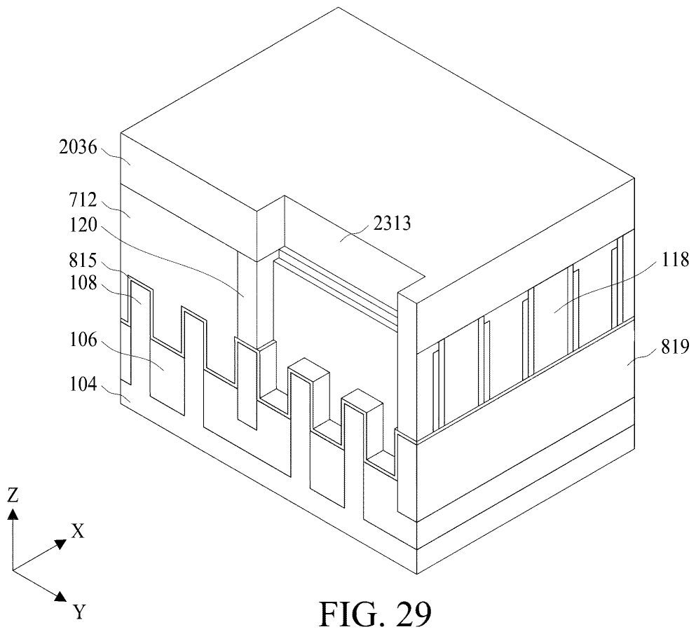

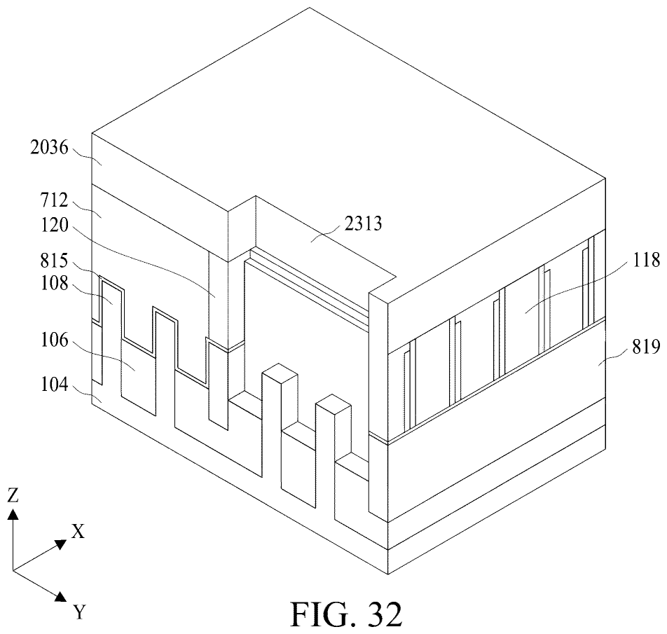

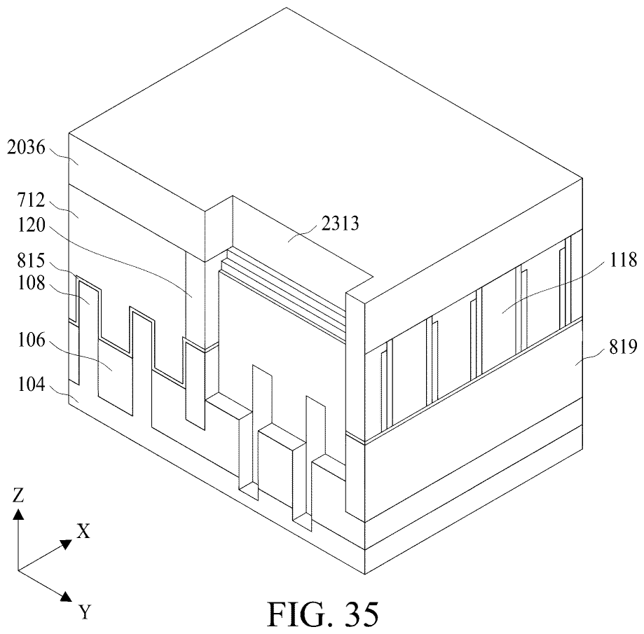

In some embodiments, a second etching process can remove sacrificial gate structures 712 and extend opening 2313 through sacrificial gate structures 712, as shown in FIGS. 29-31. In some embodiments, the etching of sacrificial gate structures 712 can be directional and self-aligned. The etchants can include hydrogen bromide-based plasma with an addition of oxygen or carbon dioxide. In some embodiments, the plasma etching process can use a bias power with zero source power to increase the directionality of the etching process. In some embodiments, a third etching process can remove protection layer 815 on fin structures 108 and STI regions 106, as shown in FIGS. 32-34. In some embodiments, a fourth etching process can etch through fin structures 108 and extend opening 2313 into substrate 104, as shown in FIGS. 35-37.

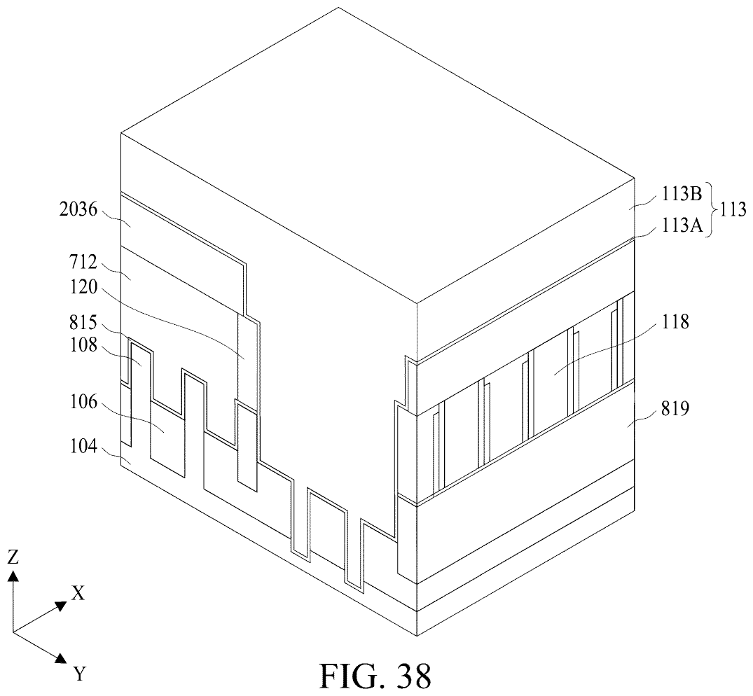

The formation of opening 2313 through sacrificial gate structures 712 and fin structures 108 can be followed by forming trench isolation structures 113 in opening 2313, as shown in FIGS. 38-44. In some embodiments, trench isolation structures 113 can include liner 113A and dielectric fill 113B. Liner 113A can be conformally deposited on hard mask layer 2036, substrate 104, and sidewalls of STI regions 106, dielectric fin structures 819, dielectric frame structures 120, and gate spacers 114. Dielectric fill 113B can be blanket deposited on liner 113A and can fill opening 2313, as shown in FIGS. 38-40. In some embodiments, a CMP process can planarize top surfaces of gate spacers 114, ESL 116, ILD layer 118, trench isolation structures 113, dielectric frame structures 120, and sacrificial gate structures 712. In some embodiments, as shown in FIG. 44 with no dielectric fin structures 819, dielectric frame structures 120 can extend through sacrificial gate structures 712 into STI regions 106. Dielectric frame structures 120 can be in contact with end portions of trench isolation structures 113.

In some embodiments, trench isolation structures 113 can include silicon oxide, silicon nitride, silicon oxynitride, silicon oxycarbonitride, or other suitable dielectric materials. In some embodiments, trench isolation structures 113 can extend through sacrificial gate structures 712, STI regions 106, and fin structures 108 into substrate 104. In some embodiments, trench isolation structures 113 can be formed by the CPODE process to reduce leakage current flowing through S/D structures 110, fin structures 108, and substrate 104.

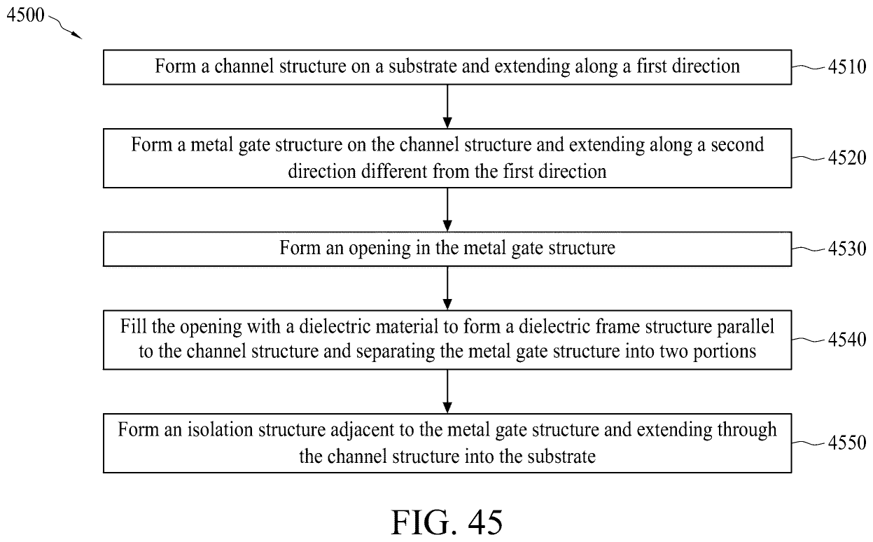

Referring to FIG. 6, in operation 660, the sacrificial gate structure can be replaced with a metal gate structure. For example, as shown in FIGS. 1-5, sacrificial gate structures 712 can be replaced with metal gate structures 112. In some embodiments, the replacement of gate structures 112 can include removal of sacrificial gate structures 712 and deposition of gate structures 112, the processes of which are not described in detail for clarity. In some embodiments, trench isolation structures 113 can be formed after the replacement of gate structures 112, as described in FIGS. 45-83.

FIG. 45 is a flow diagram of another method 4500 for fabricating semiconductor device 100 having a dielectric frame structure, in accordance with some embodiments. Method 4500 may not be limited to nanostructure transistor devices and can be applicable to other devices that would benefit from the dielectric frame structure. Additional fabrication operations may be performed between various operations of method 4500 and may be omitted merely for clarity and ease of description. Additional processes can be provided before, during, and/or after method 4500; one or more of these additional processes are briefly described herein. Moreover, not all operations may be needed to perform the disclosure provided herein. Additionally, some of the operations may be performed simultaneously or in a different order than shown in FIG. 45. In some embodiments, one or more other operations may be performed in addition to or in place of the presently-described operations.

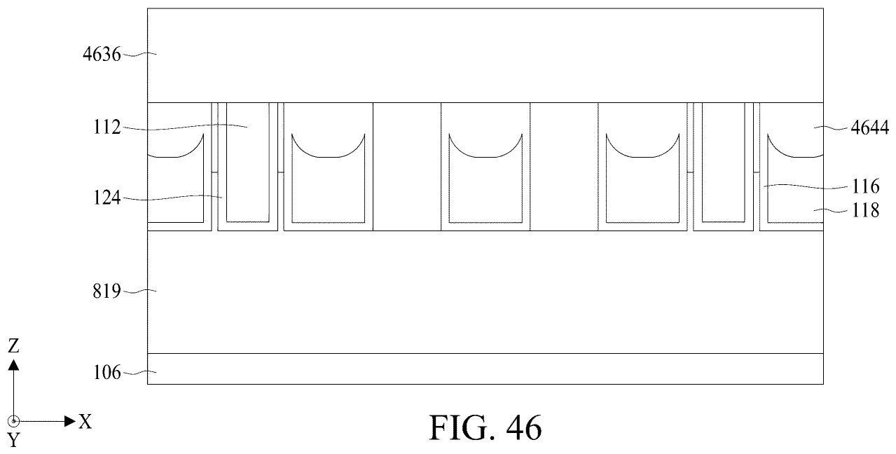

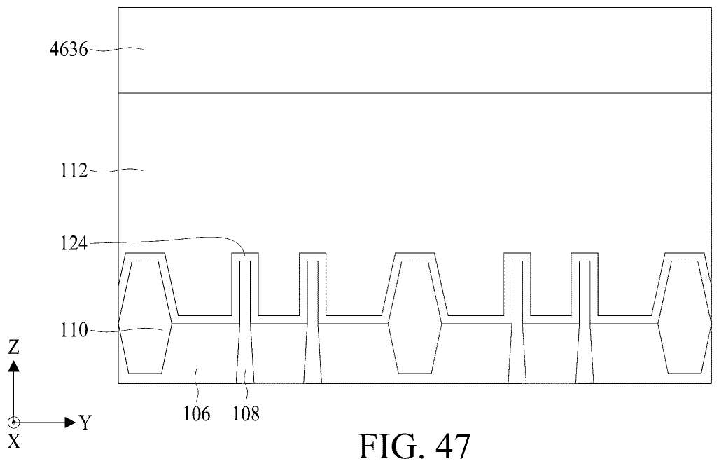

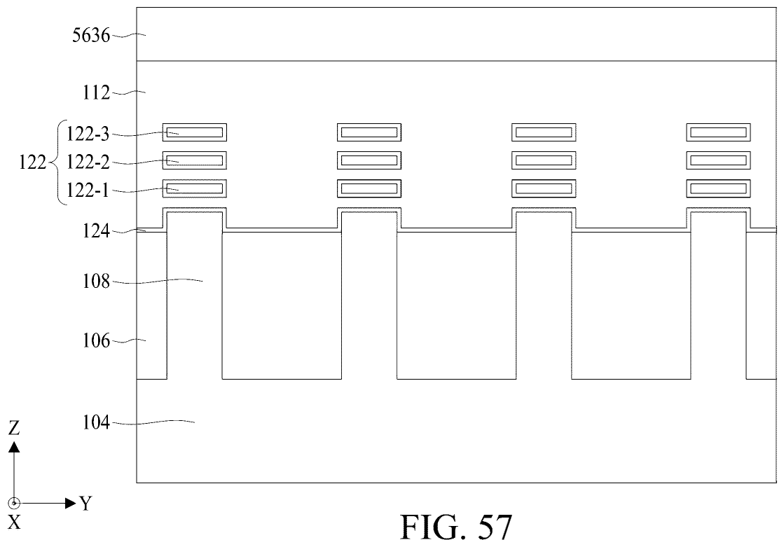

For illustrative purposes, the operations illustrated in FIG. 45 will be described with reference to the example fabrication process for fabricating semiconductor device 100 as illustrated in FIGS. 46-83. FIGS. 46-83 illustrate partial cross-sectional views of semiconductor device 100 having a dielectric frame structure at various stages of its fabrication using another method, in accordance with some embodiments. FIGS. 46, 48, 50, 52, 54, 64, 66, 68, 70, 72, 74, 76, 78, 80, and 82 illustrate partial cross-sectional views of semiconductor device 100 along an X-axis (e.g., line A-A as shown in FIG. 2) at various stages of its fabrication using another method, in accordance with some embodiments. FIGS. 47, 49, 51, 53, 55-63, 65, 67, 69, 71, 73, 75, 77, 79, 81, and 83 illustrate partial cross-sectional views of semiconductor device 100 along a Y-axis (e.g., line B-B as shown in FIG. 2) at various stages of its fabrication using another method, in accordance with some embodiments. In some embodiments, FIGS. 56, 58, 60, and 62 illustrate partial cross-sectional views of semiconductor device 100 along the Y-axis over STI regions 106. In some embodiments, FIGS. 57, 59, 61, and 63 illustrate partial cross-sectional views of semiconductor device 100 along the Y-axis over nanostructures 122. Elements in FIGS. 46-83 with the same annotations as elements in FIGS. 1-44 are described above.

In referring to FIG. 45, method 4500 begins with operation 4510 and the process of forming a channel structure on a substrate and extending along a first direction. For example, as shown in FIGS. 46 and 47, fin structures 108 can be formed on substrate 104 along an X-axis and fin structures 108 can act as the channel structures. In some embodiments, as shown in FIGS. 46 and 47, gate dielectric layer 124 can be conformally deposited on STI regions 106 and fin structures 108. In another example, as shown in FIGS. 56 and 57, a stack of nanostructures 122 and fin structures 108 can be formed on substrate 104 along an X-axis and nanostructures 122 can act as the channel structures. In some embodiments, as shown in FIGS. 56 and 57, gate dielectric layer 124 can be conformally deposited on nanostructures 122, fin structures 108, and STI regions 106. In some embodiments, bumps of STI regions 106 under gate structures 112 in FIGS. 56, 58, 60, and 62 can be removed after the formation of gate structures 112 using a highly selective etch process. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the high-k dielectric layer can include hafnium oxide, zirconium oxide, or other suitable high-k dielectric materials.

Referring to FIG. 45, in operation 4520, a metal gate structure can be formed on the channel structure and extending along a second direction different from the first direction. For example, as shown in FIGS. 46 and 47, metal gate structures 112 can be formed on fin structures 108 extending along a Y-axis. In another example, as shown in FIGS. 56 and 57, metal gate structures 112 can wrap around nanostructures 122 and can extend along a Y-axis. In some embodiments, gate structures 112 can include one or more work function metal layers and a metal fill.

In some embodiments, as shown in FIGS. 46 and 47, gate structures 112 can be deposited on gate dielectric layer 124 over fin structures 108, dielectric fin structures 819, and STI regions 106. In some embodiments, as shown in FIGS. 56 and 57, gate structures 112 can be deposited on gate dielectric layer 124 around nanostructures 122 and over fin structures 108 and STI regions 106. In some embodiments, gate structures 112 can be patterned to extend along the Y-axis. In some embodiments, as shown in FIGS. 46, 47, 56, and 57, gate spacers 114, ESL 116, and ILD layer 118 can be formed between adjacent gate structures 112. In some embodiments, as shown in FIGS. 46 and 47, hard mask layer 4644 can be formed on ILD layer 118. In some embodiments, as shown in FIGS. 46 and 47, a CMP process can planarize top surfaces of gate structures 112, ESL 116, and hard mask layer 4644. In some embodiments, a hard mask layer 4636 can be deposited on the planarized top surfaces of gate structures 112, ESL 116, and hard mask layer 4644. In some embodiments, as shown in FIGS. 56 and 57, a CMP process can planarize top surfaces of gate structures 112, gate spacers 114, ESL 116, and ILD layer 118. In some embodiments, as shown in FIGS. 56 and 57, a hard mask layer 5636 can be deposited on the planarized top surfaces of gate structures 112, gate spacers 114, ESL 116, and ILD layer 118.

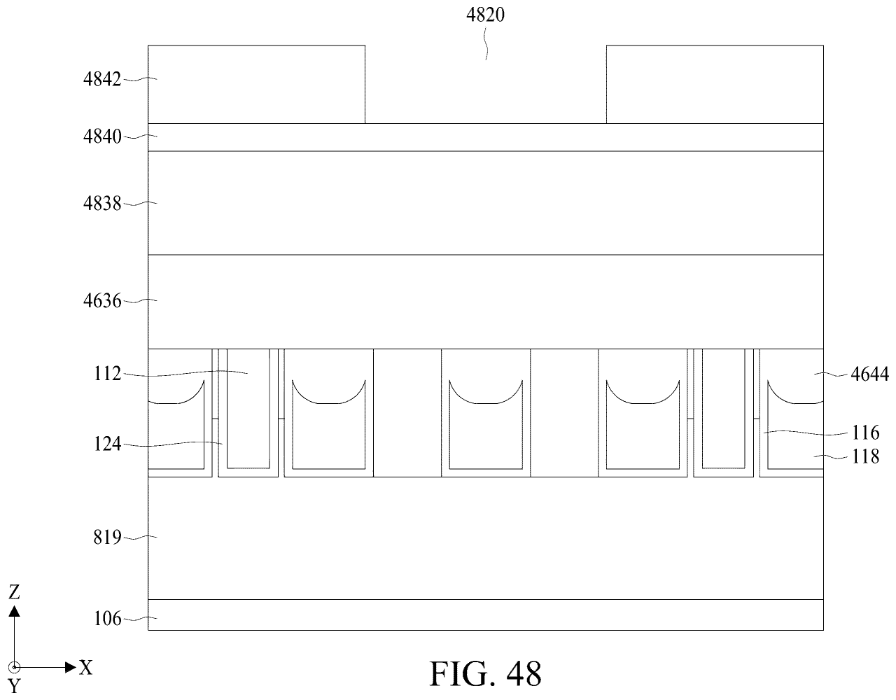

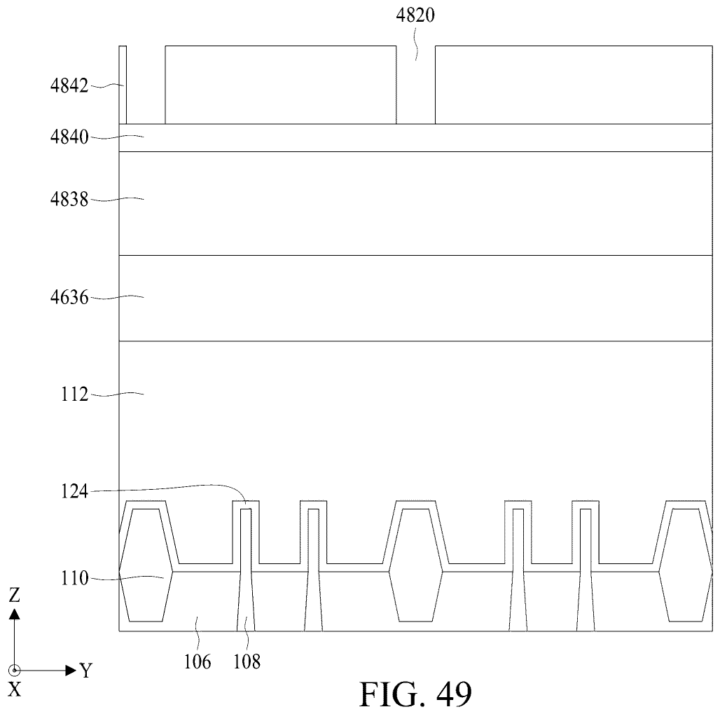

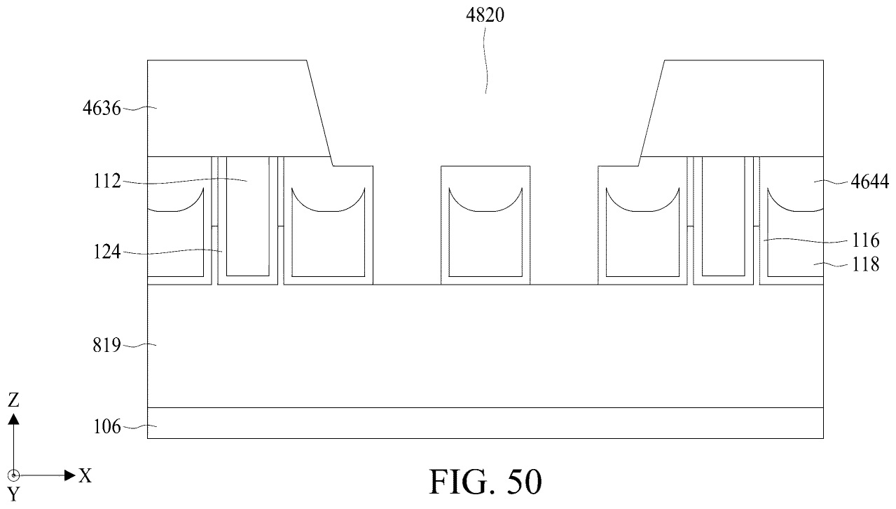

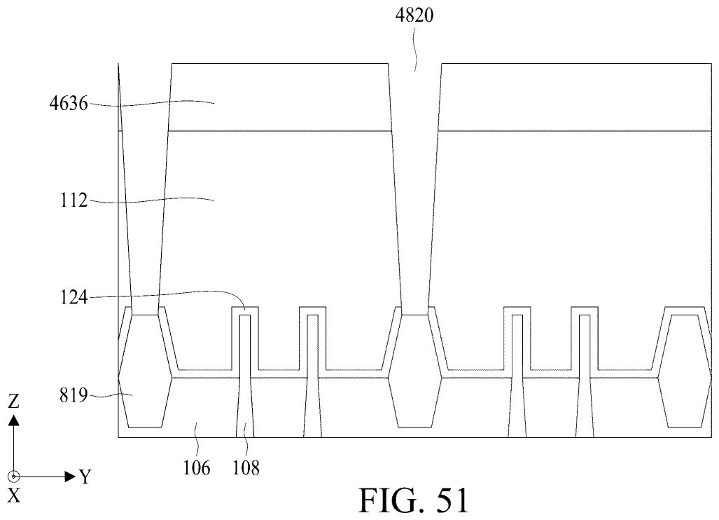

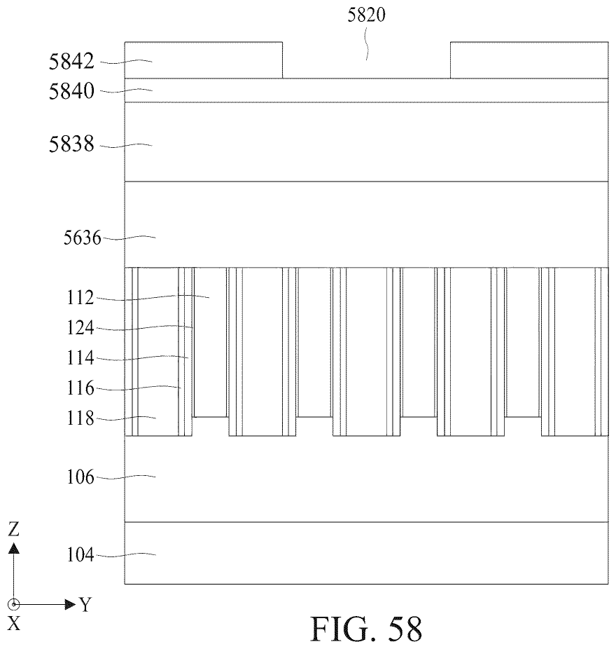

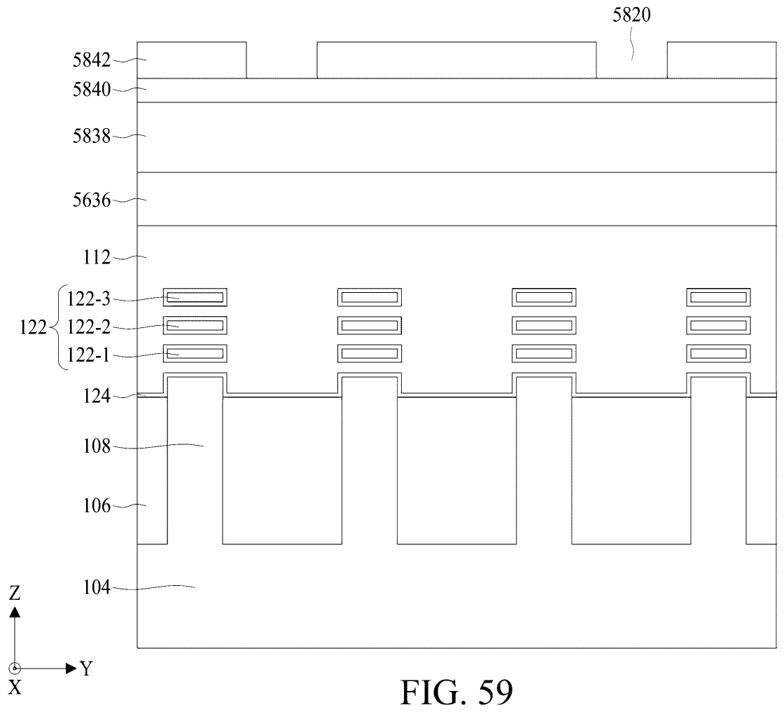

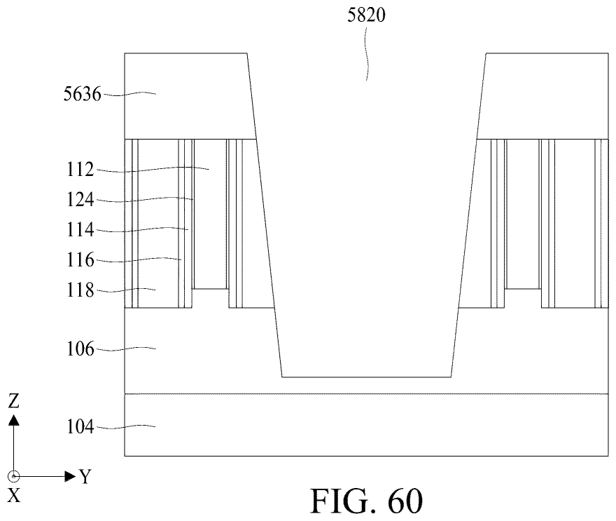

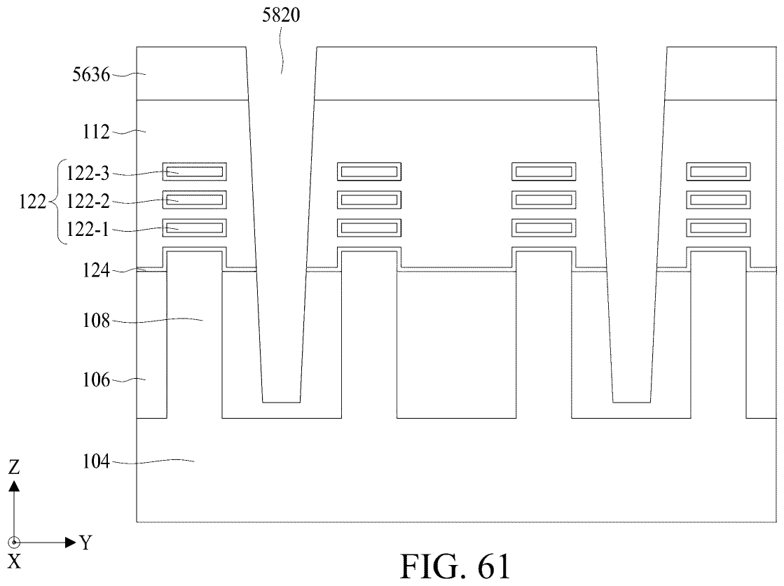

Referring to FIG. 45, in operation 4530, an opening is formed in the metal gate structure. For example, as shown in FIGS. 48-51, openings 4820 can be formed in metal gate structures 112. In another example, as shown in FIGS. 58-61, openings 5820 can be formed in metal gate structures 112. In some embodiments, as shown in FIGS. 48 and 49, a stack of bottom layer 4838, middle layer 4840, and photoresist 4842 can be deposited on hard mask layer 4636. Openings 4820 can be patterned in photoresist 4842 above gate structures 112. After the patterning process, one or more etching processes can remove hard mask layer 4636 and gate structures 112 under openings 4820 and can expose hard mask layer 4644, ESL 116, and dielectric fin structures 819, as shown in FIGS. 50 and 51. In some embodiments, as shown in FIGS. 58 and 59, a stack of bottom layer 5838, middle layer 5840, and photoresist 5842 can be deposited on hard mask layer 5836. Openings 5820 can be patterned in photoresist 5842 above gate structures 112. After the patterning process, one or more etching processes can remove hard mask layer 5836 and gate structures 112 under openings 5820 and can expose ILD layer 118 and STI regions 106, as shown in FIGS. 60 and 61.

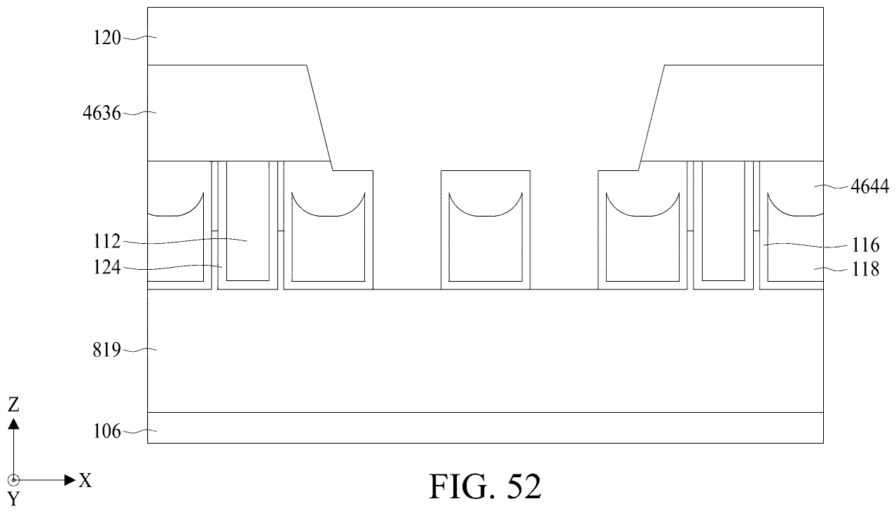

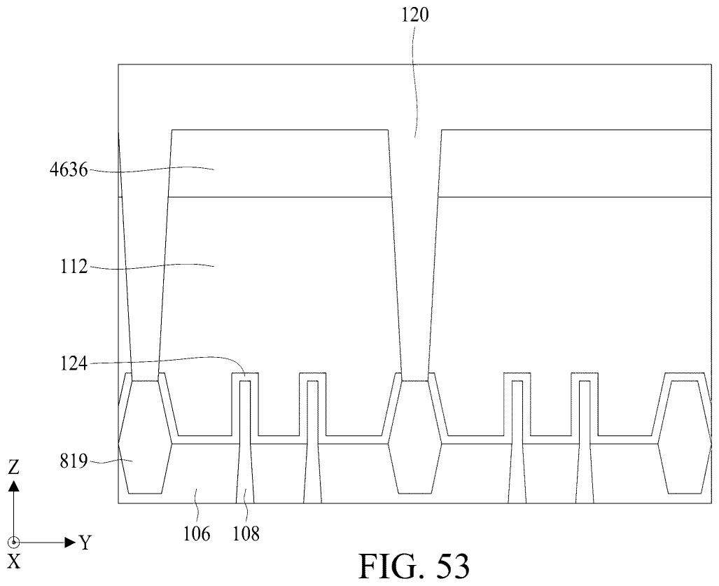

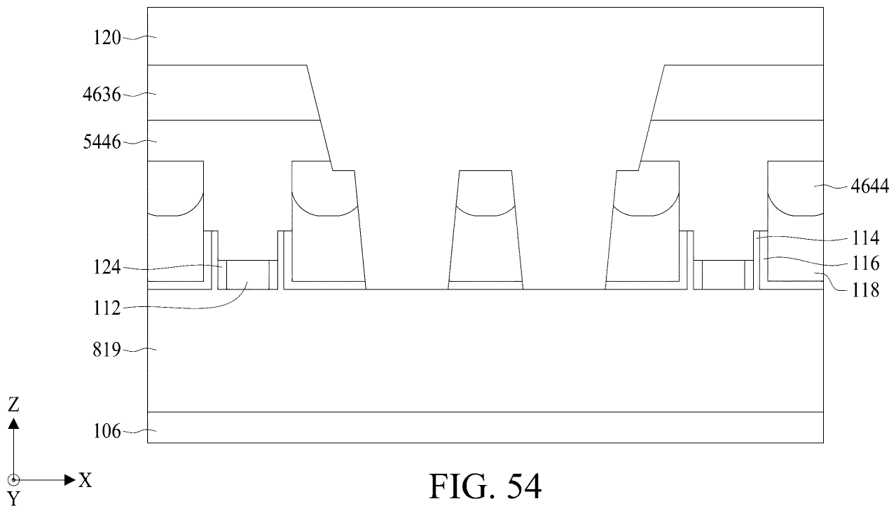

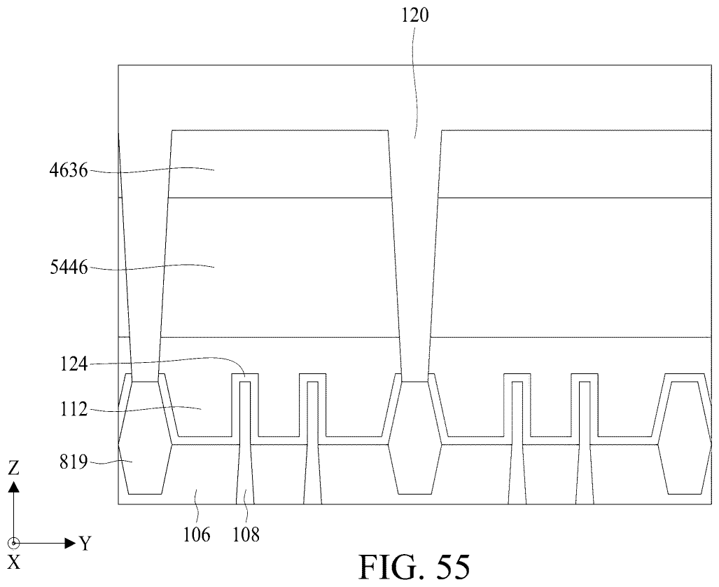

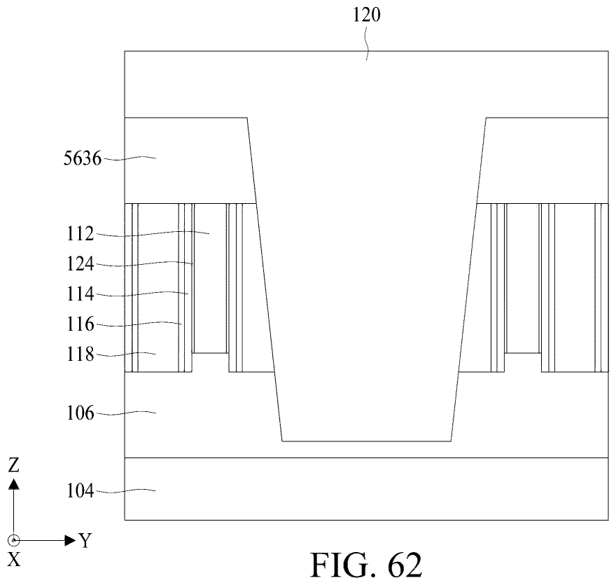

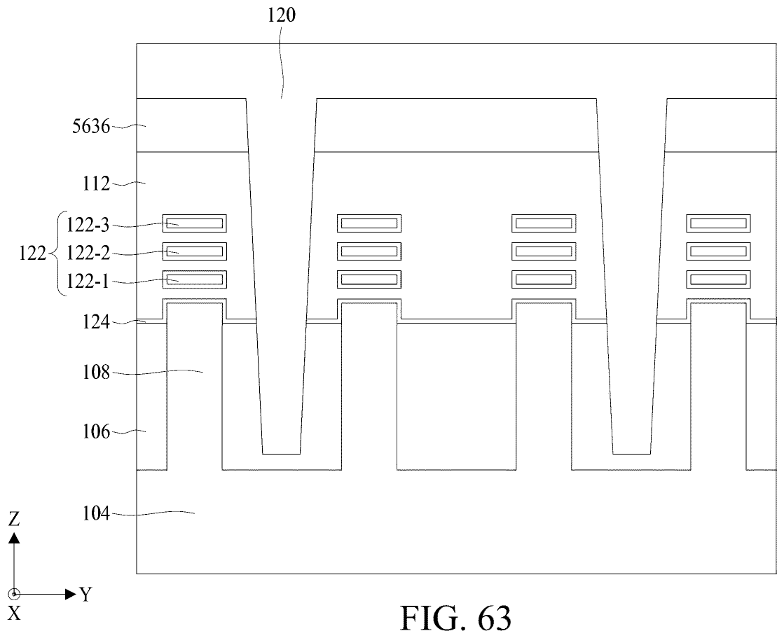

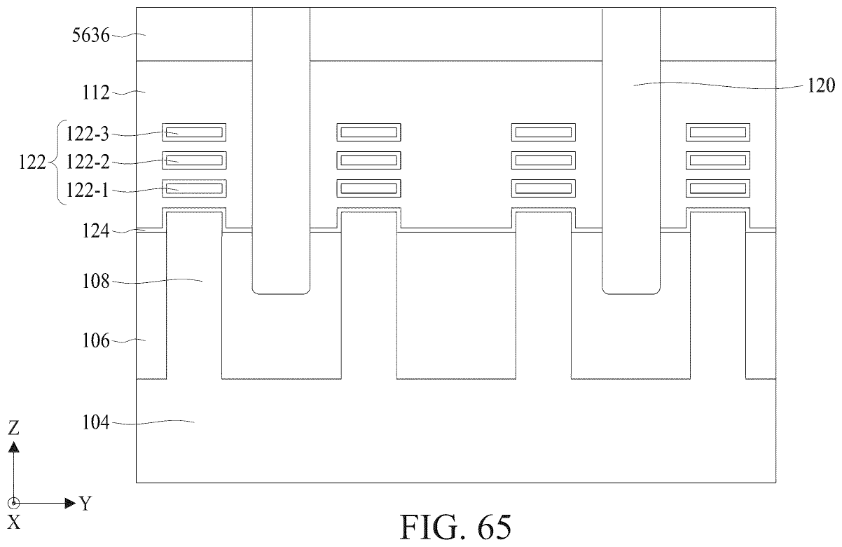

Referring to FIG. 45, in operation 4540, a dielectric material is filled in the opening to form a dielectric frame structure parallel to the channel structure and separating the metal gate structure into two portions. For example, as shown in FIGS. 52 and 53, a stiff dielectric material can be blanket deposited on hard mask layer 4636 to fill openings 4820 and form dielectric frame structures 120. In some embodiments, dielectric frame structures 120 can extend along an X-axis parallel to fin structures 108. In some embodiments, as shown in FIGS. 52 and 53, dielectric frame structures 120 and dielectric fin structures 819 can extend vertically through gate structures 112. Dielectric frame structures 120 and dielectric fin structures 819 can electrically isolate gate structures 112 into two portions. In some embodiments, as shown in FIGS. 54 and 55, a dielectric layer 5446 can be formed on gate structures 112 for self-aligned contact (SAC) process. The one or more etching process can etch through hard mask layer 4636, dielectric layer 5446, and gate structures 112 to expose dielectric fin structures 819. Dielectric frame structures 120 can be in contact with hard mask layer 4636, hard mask layer 4644, dielectric layer 5446, ILD layer 118, and dielectric fin structures 819. In another example, as shown in FIGS. 62 and 63, a stiff dielectric material can be blanket deposited on hard mask layer 5636 to fill openings 5820 and form dielectric frame structures 120. In some embodiments, as shown in FIGS. 62-65, dielectric frame structures 120 can extend vertically through gate structures 112 into STI regions 106 and can act as gate isolation structures, such as CPO or CMG dielectric structures. In some embodiments, as shown in FIG. 65, a CMP process can planarize top surfaces of hard mask layer 5636 and dielectric frame structures 120.

In some embodiments, the stiff dielectric material in dielectric frame structures 120 can have a Young's modulus greater than that of silicon oxide. In some embodiments, the stiff dielectric material can have a Young's modulus greater than about 75 GPa. In some embodiments, the stiff dielectric material can include hafnium oxide, zirconium oxide, or other suitable high-k dielectric materials. In some embodiments, the stiff dielectric material can include silicon nitride, silicon carbide, silicon carbonitride, silicon oxycarbonitride, silicon, aluminum oxide, or other suitable lower k dielectric materials. In some embodiments, dielectric frame structures 120 can have a higher etch resistivity and can remain after the etching during the CPODE and/or CMODE processes.

In some embodiments, as shown in FIGS. 53 and 55, dielectric frame structures 120 and fin structures 108 can be disposed on substrate 104 in an alternate configuration. In some embodiments, as shown in FIGS. 53-56, bottom surfaces of dielectric frame structures 120 can be above the top surfaces of STI regions 106. In some embodiments, as shown in FIGS. 62-65, dielectric frame structures 120 and nanostructures 122 can be disposed on substrate 104 in an alternate configuration. In some embodiments, as shown in FIGS. 62-65, bottom surfaces of dielectric frame structures 120 can be below the top surfaces of STI regions 106. In some embodiments, dielectric frame structures 120 can reduce the deformation of substrate 104 caused by the CPODE or CMODE processes and minimize the LDE effect of semiconductor device 100 on substrate 104. As a result, dielectric frame structures 120 can reduce leakage current caused by the iso-dense depth loading effect, minimize damage to S/D epitaxial structures caused by the iso-dense critical dimension loading effect, and reduce Vt shift of semiconductor device 100 caused by gate deformation.

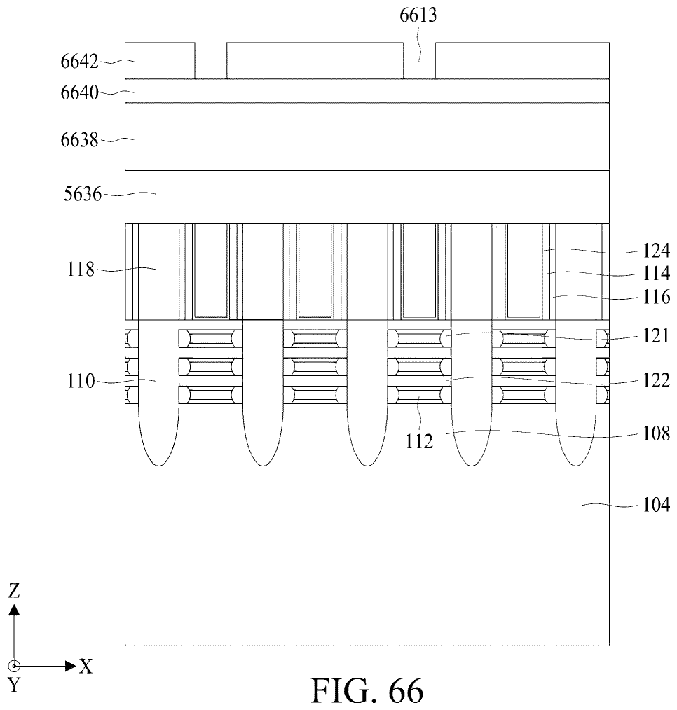

Referring to FIG. 45, in operation 4550, an isolation structure is formed adjacent to the metal gate structure and extending through the channel structure into the substrate. For example, as shown in FIGS. 66-83, trench isolation structures 113 can be formed adjacent to metal gate structures 112 and extending through nanostructures 122 and fin structures 108 into substrate 104. In some embodiments, end portions of trench isolation structures 113 can be in contact with dielectric frame structures 120. In some embodiments, the formation of trench isolation structures 113 can include forming an opening 6613 through gate structures 112, nanostructures 122, and fin structures 108 and depositing a dielectric material in opening 6613.

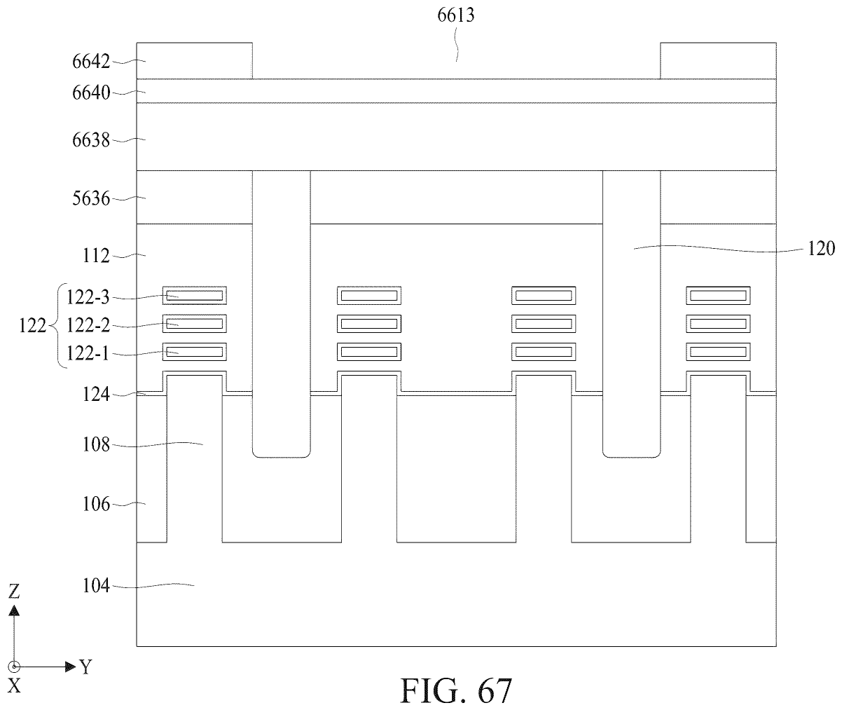

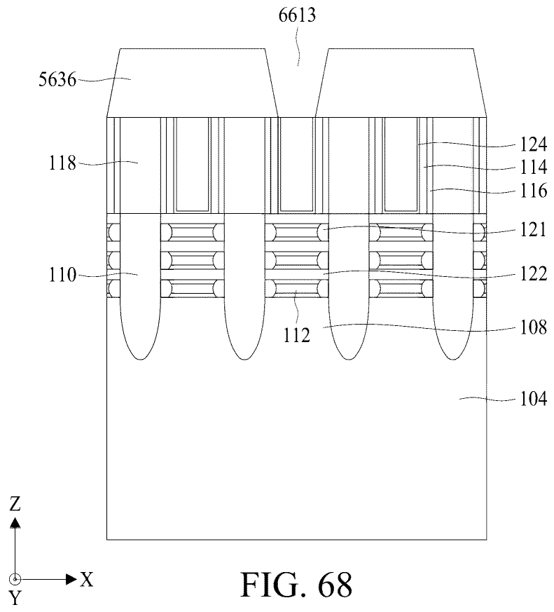

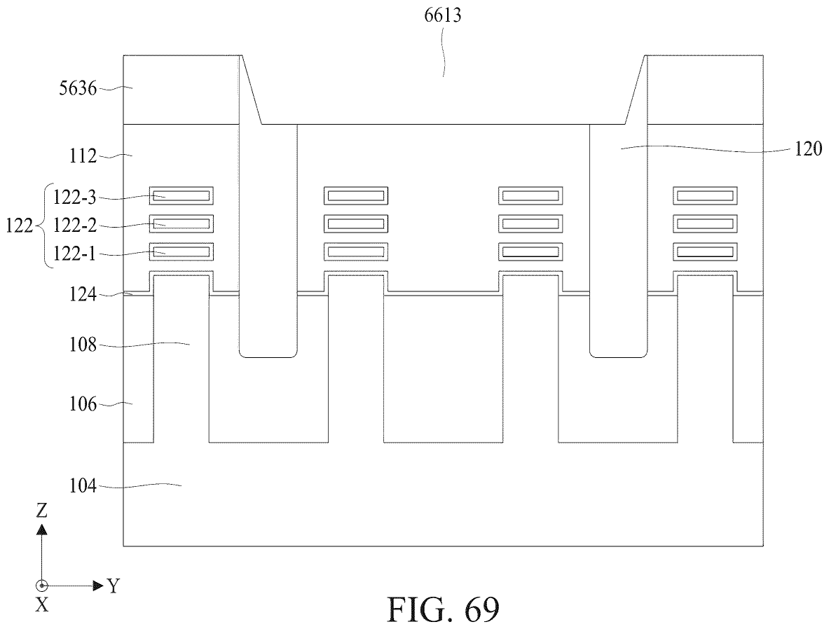

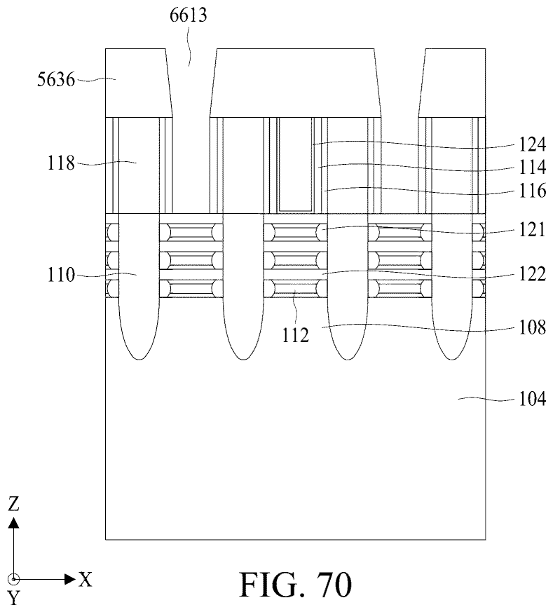

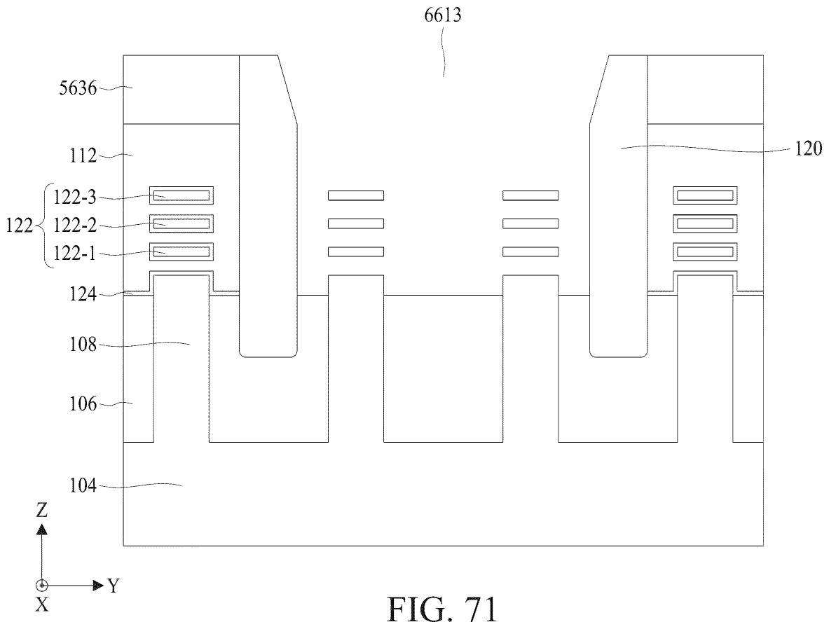

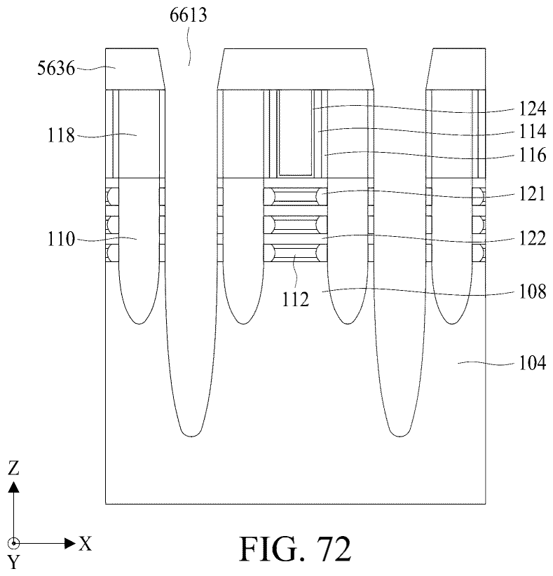

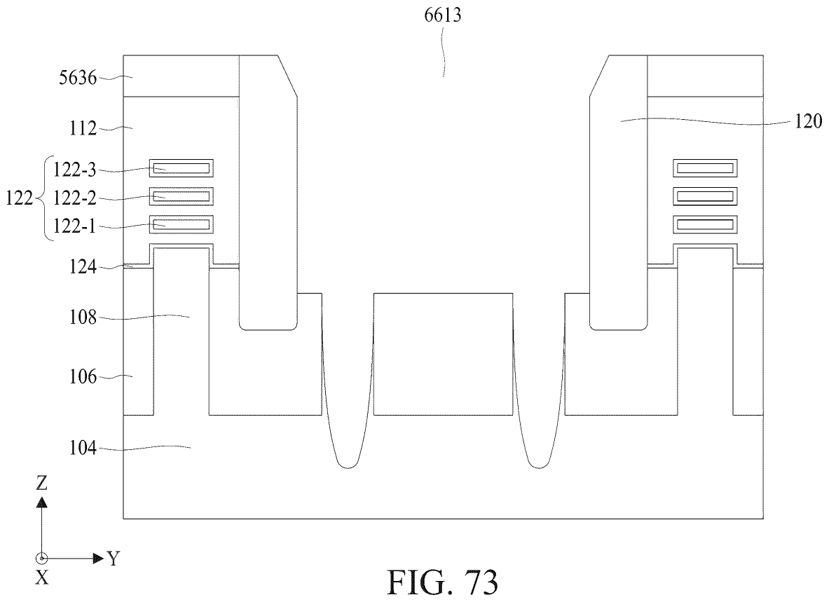

In some embodiments, as shown in FIGS. 66 and 67, a stack of bottom layer 6638, middle layer 6640, and photoresist 6642 can be deposited on planarized top surfaces of dielectric frame structures 120 and hard mask layer 5636. In some embodiments, opening 6613 can be patterned in photoresist 6642 above gate structures 112, as shown in FIGS. 66 and 67. After the patterning process, opening 6613 can be formed in hard mask layer 6636 by a first etching process, as shown in FIGS. 68 and 69. In some embodiments, a second etching process can remove gate structures 112 and extend opening 6613 through gate structures 112, as shown in FIGS. 70 and 71. In some embodiments, the etching of gate structures 112 can be directional and self-aligned. In some embodiments, a third etching process can etch through nanostructures 122 and fin structures 108 and extend opening 6613 into substrate 104, as shown in FIGS. 72 and 73. In some embodiments, the second and third etching processes can have a high etching selectivity and STI regions 106 between fin structures 108 may not be removed after the third etching process.

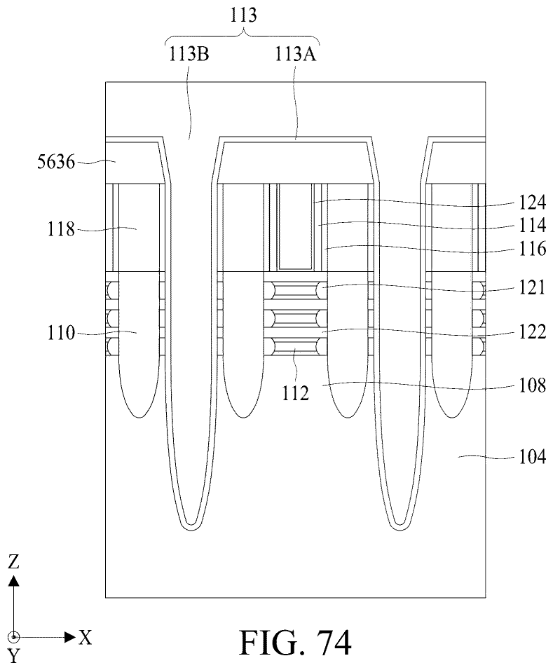

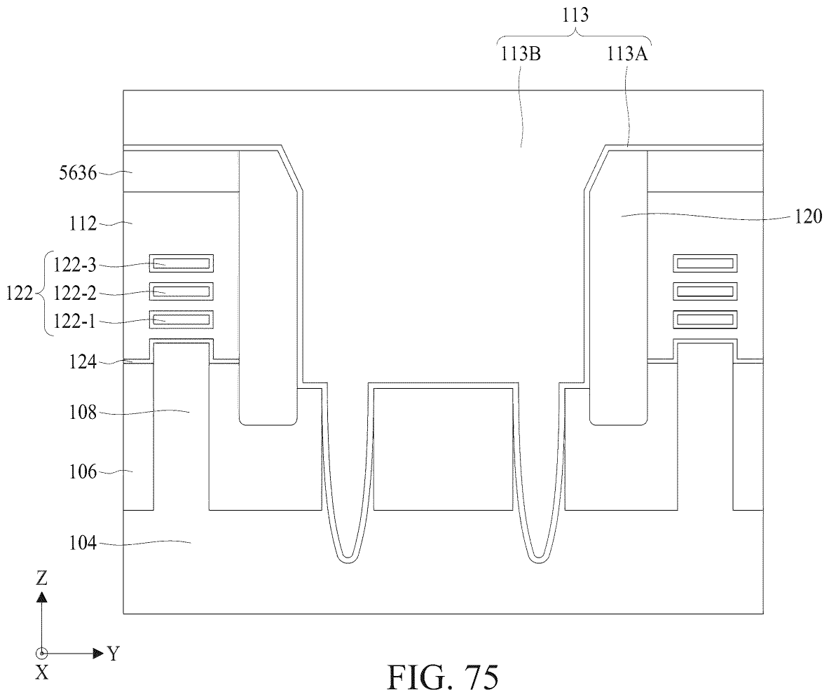

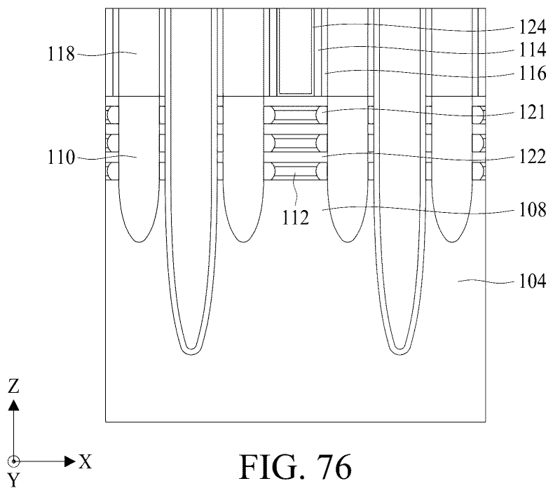

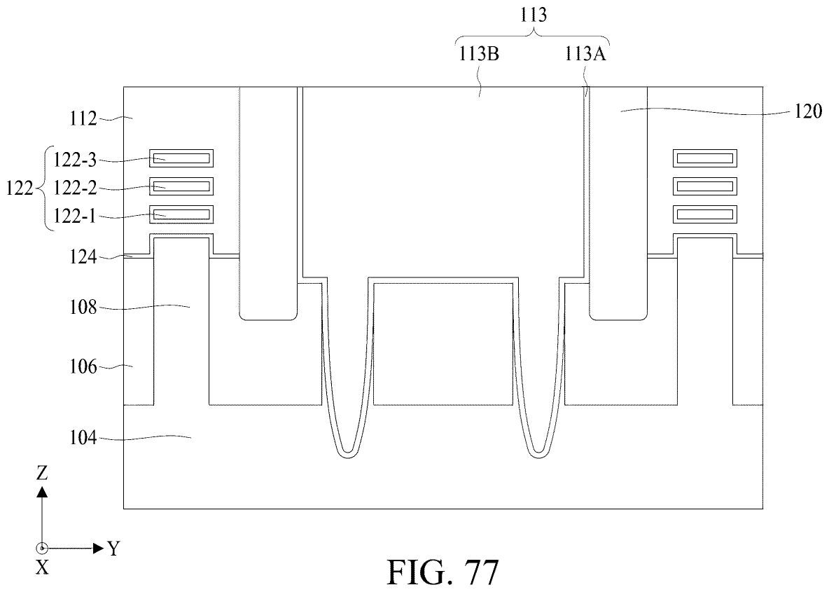

The formation of opening 6613 through gate structures 112, nanostructures 122, and fin structures 108 can be followed by forming trench isolation structures 113 in opening 6613, as shown in FIGS. 74 and 75. In some embodiments, trench isolation structures 113 can include liner 113A and dielectric fill 113B. Liner 113A can be conformally deposited on hard mask layer 5636, substrate 104, and sidewalls of STI regions 106, dielectric frame structures 120, and gate spacers 114. Dielectric fill 113B can be blanket deposited on liner 113A and can fill opening 6613, as shown in FIGS. 74 and 75. In some embodiments, as shown in FIGS. 76 and 77, a CMP process can planarize top surfaces of gate spacers 114, ESL 116, ILD layer 118, trench isolation structures 113, dielectric frame structures 120, and gate structures 112. In some embodiments, dielectric frame structures 120 can be in contact with end portions of trench isolation structures 113.

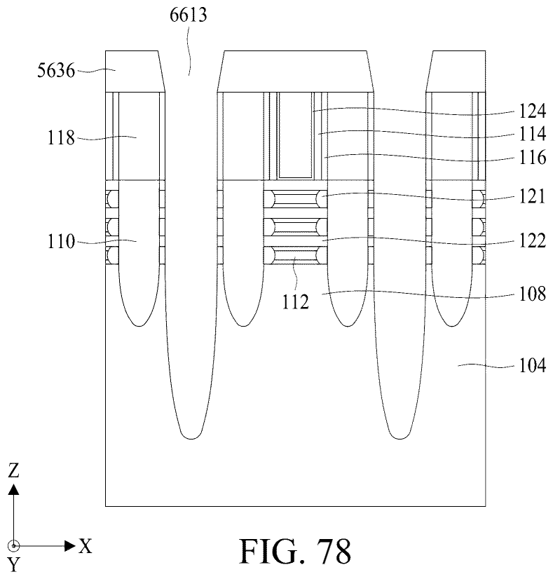

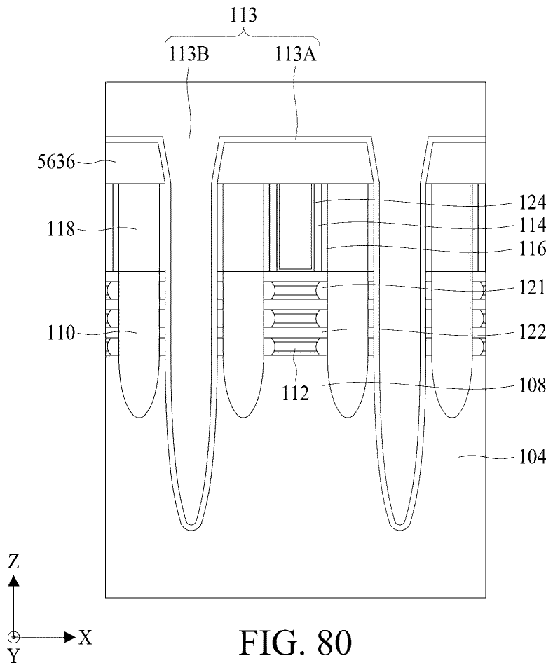

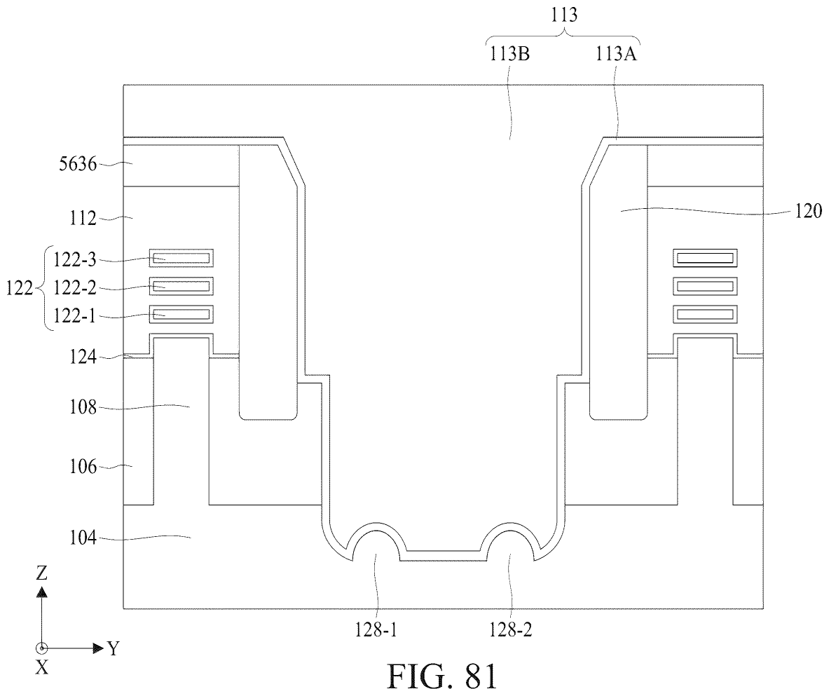

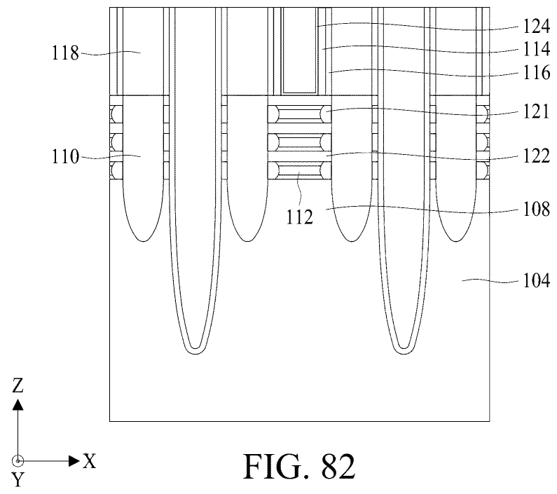

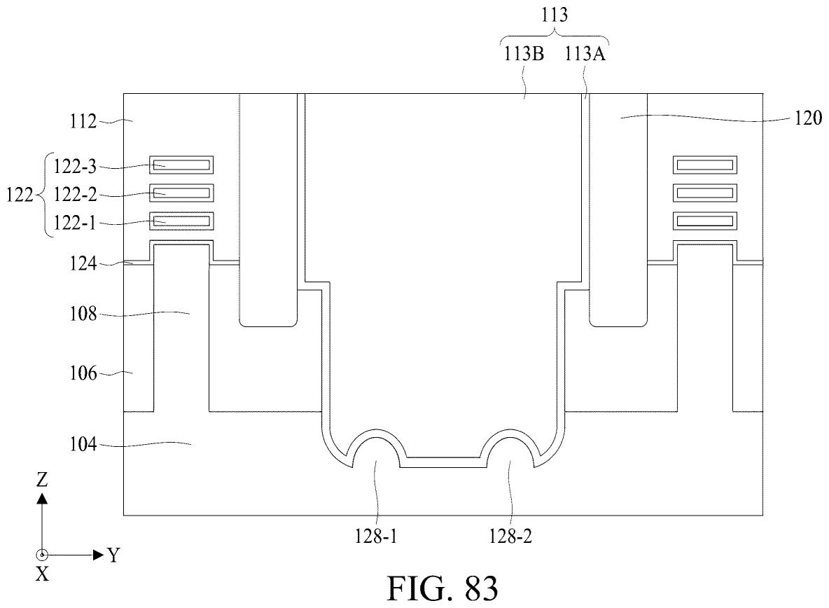

In some embodiments, as shown in FIGS. 78-83, gate structures 112, nanostructures 122, and fin structures 108 can be removed by a low selectivity etching process. In some embodiments, the low selectivity etching process can be directional and self-aligned. In some embodiments, the low selectivity etching process can remove gate structures 112, nanostructures 122, and fin structures 108 and form opening 6613 to expose substrate 104. In some embodiments, the low selectivity etching process can form two bumps 128-1 and 128-2 on substrate 104. The formation of opening 6613 through gate structures 112, nanostructures 122, and fin structures 108 can be followed by forming trench isolation structures 113 in opening 6613, as shown in FIGS. 80 and 81. In some embodiments, as shown in FIGS. 82 and 83, a CMP process can planarize top surfaces of gate spacers 114, ESL 116, ILD layer 118, trench isolation structures 113, dielectric frame structures 120, and gate structures 112. In some embodiments, dielectric frame structures 120 can be in contact with end portions of trench isolation structures 113.

In some embodiments, trench isolation structures 113 can include silicon oxide, silicon nitride, silicon oxynitride, silicon oxycarbonitride, or other suitable dielectric materials. In some embodiments, trench isolation structures 113 can extend through gate structures 112, STI regions 106, and fin structures 108 into substrate 104. In some embodiments, trench isolation structures 113 can be formed by the CMODE process to reduce leakage current flowing through S/D structures 110, fin structures 108, and substrate 104.

Various embodiments of the present disclosure provide methods for forming dielectric frame structures 120 in semiconductor device 100. In some embodiments, channel structures extending along a first direction, such as nanostructures 122 and fin structures 108, can be formed on substrate 104. Gate structures 112 can be formed on the channel structures and extending along a second direction different from the first direction. Openings 820 and 5820 can be formed in gate structures 112. A dielectric material can be filled in openings 820 and 5820 to form dielectric frame structures 120 parallel to fin structures 108 and separating gate structures 112 into two portions. In some embodiments, dielectric frame structures 120 can include a stiff dielectric material and extend along the first direction. In some embodiments, the stiff dielectric material can have a Young's modulus greater than that of silicon oxide. In some embodiments, the stiff dielectric material can have a Young's modulus greater than about 75 GPa. Trench isolation structures 113 can be formed adjacent to gate structures 112 and can extend through nanostructures 122 and fin structures 108 into substrate 104. In some embodiments, an end portion of trench isolation structures 113 can be in contact with dielectric frame structures 120. In some embodiments, trench isolation structures 113 can be formed by CPODE or CMODE processes. In some embodiments, dielectric frame structures 120 can act as gate isolation structures, such as CPO or CMG dielectric structures. In some embodiments, dielectric frame structures 120 can reduce the deformation of substrate 104 and minimize the LDE effect of the semiconductor devices on substrate 104. Accordingly, dielectric frame structures 120 can reduce device leakage current, minimize damage to S/D epitaxial structures, and reduce Vt shift of the semiconductor devices on substrate 104.

In some embodiments, a semiconductor structure includes a channel structure on a substrate and extending along a first direction, a gate structure on the channel structure and extending along a second direction different from the first direction, a dielectric frame structure on the substrate and parallel to the channel structure, and an isolation structure adjacent to the gate structure and extending through the channel structure into the substrate. The dielectric frame structure includes a dielectric material extending through the gate structure to separate the gate structure into two portions. An end portion of the isolation structure is in contact with the dielectric frame structure.

In some embodiments, a semiconductor device includes multiple channel structures on a substrate, a gate structure on the substrate and the multiple channel structures, multiple dielectric frame structures including a dielectric material and extending through the gate structure to separate the gate structure into isolated portions, and an isolation structure extending along the gate structure and through at least one of the multiple channel structures. The multiple channel structures and the multiple dielectric frame structures are arranged in an alternate configuration. The isolation structure is in contact with at least one of the multiple dielectric frame structures.

In some embodiments, a method includes forming a channel structure on a substrate and extending along a first direction, forming a gate structure on the channel structure and extending along a second direction different from the first direction, forming an opening in the gate structure, filling the opening with a dielectric material to form a dielectric frame structure parallel to the channel structure; and forming an isolation structure adjacent to the gate structure and extending through the channel structure into the substrate. The dielectric frame structure separates the gate structure into two portions. An end portion of the isolation structure is in contact with the dielectric frame structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel structure on a substrate and extending along a first direction;
a gate structure on the channel structure and extending along a second direction different from the first direction;
a dielectric frame structure adjacent to the channel structure and extending along the first direction, wherein the dielectric frame structure comprises a dielectric material extending through the gate structure; and
an isolation structure extending horizontally along the second direction and vertically through the channel structure into the substrate, wherein the isolation structure extends below the dielectric frame structure.

2. The semiconductor structure of claim 1, wherein the dielectric material has a Young's modulus greater than about 75 GPa.

3. The semiconductor structure of claim 1, wherein the dielectric frame structure is between the gate structure and the isolation structure.

4. The semiconductor structure of claim 1, wherein top surfaces of the gate structure, the dielectric frame structure, and the isolation structure are substantially coplanar.

5. The semiconductor structure of claim 1, wherein bottom surfaces of the dielectric frame structure and the isolation structure are below a bottom surface of the gate structure.

6. The semiconductor structure of claim 1, further comprising a shallow trench isolation (STI) region on the substrate and surrounding the channel structure, wherein the dielectric frame structure extends through the gate structure and into the STI region.

7. The semiconductor structure of claim 6, wherein the isolation structure extends through the STI region into the substrate.

8. The semiconductor structure of claim 6, wherein a portion of the STI region is surrounded by the isolation structure and the substrate.

9. The semiconductor structure of claim 1, wherein the isolation structure comprises a liner in contact with the dielectric frame structure and a dielectric fill on the liner.

10. A semiconductor device, comprising:
first and second channel structures on a substrate;
a first gate structure on the first channel structure;
a second gate structure on the second channel structure;
first and second dielectric frame structures between the first and second gate structures, wherein the first and second dielectric frame structures separate the first gate structure from the second gate structure; and
an isolation structure extending below the first and second channel structures into the substrate, wherein the isolation structure is between the first and second dielectric frame structures.

11. The semiconductor device of claim 10, wherein the first and second dielectric frame structures comprise a dielectric material having a Young's modulus greater than about 75 GPa.

12. The semiconductor device of claim 10, wherein the first dielectric frame structure is between the first gate structure and the isolation structure.

13. The semiconductor device of claim 10, wherein top surfaces of the first and second gate structures, the first and second dielectric frame structures, and the isolation structure are substantially coplanar.

14. The semiconductor device of claim 10, wherein bottom surfaces of the first and second dielectric frame structures are above a bottom surface of the isolation structure.

15. The semiconductor device of claim 10, further comprising a shallow trench isolation (STI) region on the substrate and between the first and second channel structures, wherein the first and second dielectric frame structures extend into the STI region.

16. The semiconductor device of claim 15, wherein the isolation structure extends through the STI region into the substrate.

17. A method, comprising:
forming first and second channel structures on a substrate;
forming a gate structure on the first and second channel structures;
forming first and second openings in the gate structure, wherein the first and second openings are between the first and second channel structures;
filling the first and second openings to form first and second dielectric frame structures; and
forming an isolation structure between the first and second dielectric frame structures and extending through the gate structure into the substrate, wherein the isolation structure and the first and second dielectric frame structures separate the gate structure.

18. The method of claim 17, further comprising forming a shallow trench isolation (STI) region on the substrate and between the first and second channel structures, wherein the first and second dielectric frame structures extend into the STI region.

19. The method of claim 17, further comprising:
forming a dielectric layer on the gate structure;
forming the first and second openings in the dielectric layer and the gate structure, wherein bottom surfaces of the first and second openings are below a bottom surface of the gate structure; and
depositing, in the first and second openings, a dielectric material having a Young's modulus greater than about 75 GPa.

20. The method of claim 17, wherein forming the isolation structure comprises:
removing a portion of the gate structure between the first and second dielectric frame structures to form an opening;
removing additional channel structures in the opening, wherein the opening extends into the substrate; and
depositing a dielectric material in the opening, wherein the dielectric material is in contact with the first and second dielectric frame structures.
